(19) United States
(12) Patent Application Publication
(10) Pub. No.: US 2026/0334253 A1
(43) Pub. Date: Oct. 22, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Roger St. Amand, Tempe, AZ (US); Mike Kelly, Mesa, AZ (US)

(73) Assignee: Amkor Technology Singapore Holding Pte. Ltd., (omitted)

(21) Appl. No.: 19/639,085

(22) Filed: Apr. 3, 2026

Related U.S. Application Data
(60) Provisional application No. 63/789,605, filed on Apr. 16, 2025.

(51) Int. Cl. H10W 70/60; H10B 80/00; H10D 80/30; H10W 70/00; H10W 70/05; H10W 72/00; H10W 76/63; H10W 90/00; H10W 90/10

(52) U.S. Cl. CPC H10W 70/618; H10W 70/099; H10W 72/823; H10W 76/63; H10W 90/10; H10W 90/401; H10B 80/00; H10D 80/30

(57) ABSTRACT

In one example, an electronic device comprises a substrate and a first module coupled to the substrate. The first module includes a first electronic component, a second electronic component disposed adjacent the first electronic component, and a first bridge die coupled to the first electronic component and the second electronic component. The first electronic component and the second electronic component are in communication across the first bridge die. A second module is coupled to the substrate adjacent the first module. A second bridge die is coupled to the substrate, the first module, and the second module. The first module and the second module are in communication across the second bridge die. The substrate can defines a cavity with the second bridge die disposed in the cavity. A redistribution structure can be disposed over the substrate and covering the cavity.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A shows a top view of an example electronic device.

FIG. 1B shows a cross-sectional view of an example electronic device taken along line B-B′ in FIG. 1A.

FIGS. 2A-2I show an example method of making an electronic module using cross-sectional views.

FIGS. 3A-3F show an example method of making an electronic device using cross-sectional views.

FIG. 4 shows a cross-sectional view of an example electronic device.

FIG. 5 shows a cross-sectional view of an example electronic device.

FIG. 6 shows a cross-sectional view of an example electronic device.

FIGS. 7A to 7K show an example method of making an electronic device using cross-sectional views.

FIG. 8A shows a top view of an example electronic device.

FIG. 8B shows a cross-sectional view of an example electronic device, taken along line L-L′ in FIG. 8A.

FIGS. 9A to 9G show an example method of making an electronic device using cross-sectional views.

FIG. 10A shows a top view of an example electronic device.

FIG. 10B shows a cross-sectional view of an example electronic device, taken along line L-L′ in FIG. 10A.

FIGS. 11A to 11G show an example method of making an electronic device using cross-sectional views.

FIG. 12 shows a cross-sectional view of an example electronic device.

FIG. 13 shows a cross-sectional view of an example electronic device.

FIGS. 14A to 14G show an example method of making an electronic device using cross-sectional views.

FIGS. 15A to 15G show an example method of making an electronic device using cross-sectional views.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein as labels to describe various elements, and these elements should not be limited by these terms. These terms are only used to distinguish one element from another. Thus, for example, a first element discussed in this disclosure could be termed a second element elsewhere without departing from the teachings of the present disclosure. Similarly, terms disclosed as singular can be plural in some embodiments, and elements disclosed as plural can be singular in some embodiments.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other, describe two elements indirectly coupled by one or more other elements, or two elements overlapping vertically as depicted. Unless specified otherwise, the term “coupled” can refer to a mechanical coupling or an electrical coupling.

### DESCRIPTION

An example electronic device comprises a substrate and a first module coupled to the substrate. The first module includes a first electronic component, a second electronic component disposed adjacent the first electronic component, and a first bridge die coupled to the first electronic component and the second electronic component. The first electronic component and the second electronic component are in communication across the first bridge die. A second module is coupled to the substrate adjacent the first module. A second bridge die is coupled to the substrate, the first module, and the second module. The first module and the second module are in communication across the second bridge die.

In various examples, the substrate defines a cavity with the second bridge die disposed in the cavity. A redistribution structure can be disposed over the substrate and covering the cavity. The substrate can include a redistribution structure disposed between the second bridge die and the first module, and between the second bridge die and the second module. A stiffener can be coupled to the redistribution structure around the first module and the second module. A lid can be coupled to the redistribution structure by an adhesive. The first module can include an interconnect component coupled to the first electronic component. The first electronic component of the first module can be in communication with the second module through the interconnect component and through the second bridge die. The first bridge die and the interconnect component are embedded in an encapsulant of the first module. A backside metallization can be coupled to the second module and to the first electronic component and the second electronic component of the first module.

Another example electronic device includes a module bridge, vertical interconnects disposed around the module bridge, and an encapsulant disposed around the module bridge and the vertical interconnects. A first redistribution structure can be coupled to a first side of the module bridge and the vertical interconnects. A first module is coupled to the first redistribution structure and comprises a die bridge, a first processor die in communication with the die bridge, and a first memory die adjacent the first processor die and in communication with the first processor die through the die bridge. A second module is coupled to the first redistribution structure and in communication with the first module through the module bridge.

An example method of manufacturing an electronic device includes the steps of providing a module bridge die, providing vertical interconnects around the module bridge die, and providing a first redistribution structure over the module bridge die and the vertical interconnects. A first module is coupled to the first redistribution structure. The first module comprises a first electronic component, a component bridge die coupled to the first electronic component, and a second electronic component coupled to the component bridge die. The first electronic component and second electronic component are in communication across the component bridge die. A second module is coupled to the first redistribution structure. The first module and the second module are in communication across the module bridge die.

In various examples, a second redistribution structure is provided over an exposed side of the module bridge die opposite the first redistribution structure. A base substrate is provided and comprises interior sidewalls defining a cavity. The module bridge die is provided in the cavity. A backside metallization is provided over the first module and the second module.

Other examples are included in the present disclosure. Such examples may be found in the figures, in the claims, or in the description of the present disclosure.

Electronic devices and methods of manufacturing the same can include multiple bridge die at varied vertical levels or at different lateral locations. Bridge die can couple adjacent die to one another, and bridge die can couple adjacent modules to one another. As used herein, the term module can mean an electronic device comprising multiple semiconductor die coupled together for inclusion in a larger electronic device. A component bridge die can couple together electronic components in the same module.

As used herein, the term module bridge can describe a bridge die that couples a module to another module. As used herein, the term die bridge can describe a bridge die that couples a die to another die. Modules can include embedded die bridges to enable communication between die included in the modules. In some examples, modules can be coupled by a module bridge embedded in a substrate or disposed on a different level than the die bridges. The die bridges can be referred to as first level bridges, and the module bridges can be referred to as second level bridges. First and second levels are merely labels and can be reversed, changed, or omitted. Using multiple bridges enables inclusion of known-good die and known-good modules in an electronic device, which can increase yields. The embedded bridges can reduce the thickness and complexity of substrates in some examples.

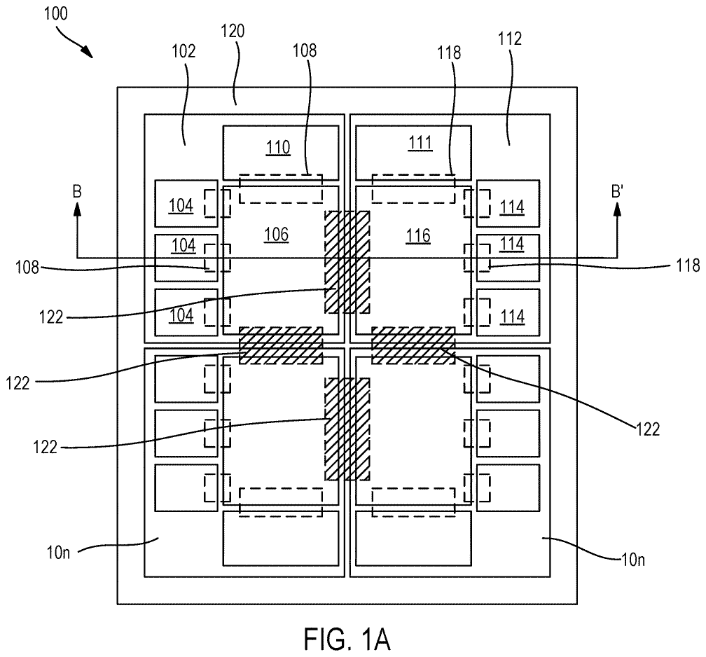

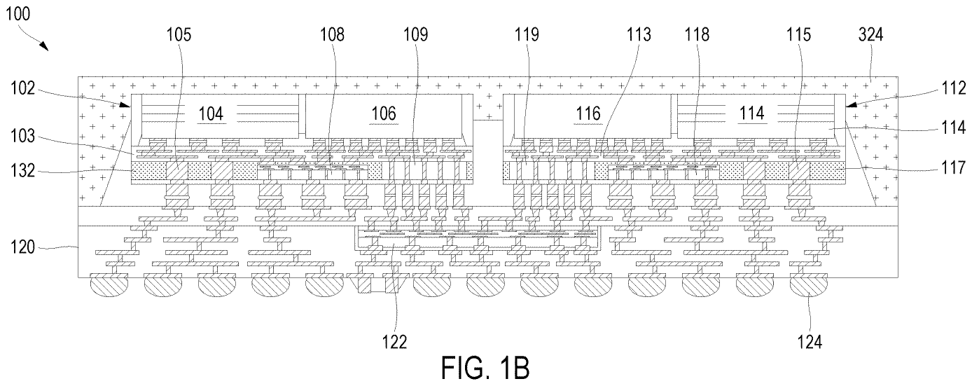

Referring now to FIGS. 1A and 1B, example electronic device 100 is shown, in accordance with various examples. Electronic device 100 can include modules 102 and 112 coupled to base substrate 120. Module 102 can comprise electronic component 104, electronic component 106, module substrate 103, bridge die 108, encapsulant 132, vertical interconnects 105, and interconnect component 109. Electronic components 104 and 106 can be coupled to module substrate 103. Module substrate 103 can be coupled between bridge die 108 and electronic components 104 and 106. Electronic component 104 and electronic component 106 can be in electronic communication across bridge die 108. In some examples, bridge die 108 can be embedded in encapsulant 132 along with vertical interconnects 105 and interconnect component 109.

In some examples, at least one of electronic component 104 and electronic component 106 can comprise a semiconductor package. For example, electronic component 104 and/or electronic component 106 can include multiple interconnected and/or stacked die and/or one or more die coupled to an interposer substrate. In some examples, electronic component 104 can comprise a memory die or memory package(s) and electronic component 106 can comprise a logic die (e.g., a central processing unit (CPU), graphics processing unit (GPU), or application specific integrated circuit (ASIC), etc.) or system on chip (SoC) die. In some examples, the memory die or memory package can comprise a high bandwidth memory (HBM) device. In some examples, the HBM device can include a controller die having a stack of memory die located thereon. The controller die and memory stack can be encapsulated.

In accordance with various examples, module 102 can further include one or more electronic component(s) 110. In some examples, electronic component 110 can comprise an input/output (I/O) die. Electronic component 110 can be coupled to module substrate 103. Module substrate 103 (also referred to herein as a redistribution structure) can be coupled between a bridge die 108 and electronic components 110 and 106. Electronic component 110 and electronic component 106 and/or electronic component 110 and electronic component 104 can be in electronic communication across the bridge die 108.

Module 112 can comprise electronic component 114, electronic component 116, module substrate 113, bridge die 118, encapsulant 117, vertical interconnects 115, and interconnect component 119. Electronic components 114 and 116 can be coupled to module substrate 113. Module substrate 113 can be coupled between bridge die 108 and electronic components 114 and 116. Electronic component 114 and electronic component 116 can be in electronic communication across bridge die 118. Bridge die 118 can be embedded in encapsulant 117 along with vertical interconnects 115 and interconnect component 119.

In some examples, at least one of electronic component 114 and electronic component 116 can comprise a semiconductor package. For example, electronic component 114 and/or electronic component 116 can include multiple interconnected and/or stacked die and/or one or more die coupled to an interposer substrate. In some examples, electronic component 114 can comprise a memory die or memory package(s) and electronic component 116 comprise a logic die (e.g., a CPU, GPU, ASIC, etc.) or SoC die. In some examples, the memory die or memory package can comprise a HBM device, as previously described.

In some examples, module 112 further include one or more electronic component(s) 111. In some examples, electronic component 111 can comprise an I/O die. Electronic component 111 can be coupled to module substrate 113. Module substrate 113 can be coupled between a bridge die 118 and electronic components 111 and 116. Electronic component 111 and electronic component 116 can be in electronic communication across the bridge die 118.

Electronic device 100 can further include bridge die 122 and base substrate 120. Bridge die 122 can be coupled to module 102 and to module 112. Module 102 and module 112 can be in electronic communication across bridge die 122. Bridge die 122 can be embedded in base substrate 120. The vertical level of bridge die 122 can be below or staggered from the vertical level of bridge die 108 and bridge die 118. External interconnects 124 can be coupled to an outer side of base substrate 120.

Interconnect components 109, 119 of modules 102, 112, respectively, can comprise through-silicon vias (TSV) or through-glass vias (TGV). Interconnect components 109, 119 can be referred to as through-via die or via die. Interconnect components 109, 119 can provide high density electrical connection (e.g., narrow pitched interconnects and/or traces) between electronic components 106, 116 and bridge die 122.

In accordance with various examples, electronic device 100 can further include one or more additional module(s) 10n. Module(s) 10n can be similar to module 102 and/or module 112. Bridge die 122 can electrically couple module(s) 10n to one another and/or to module 102 and/or to module 112.

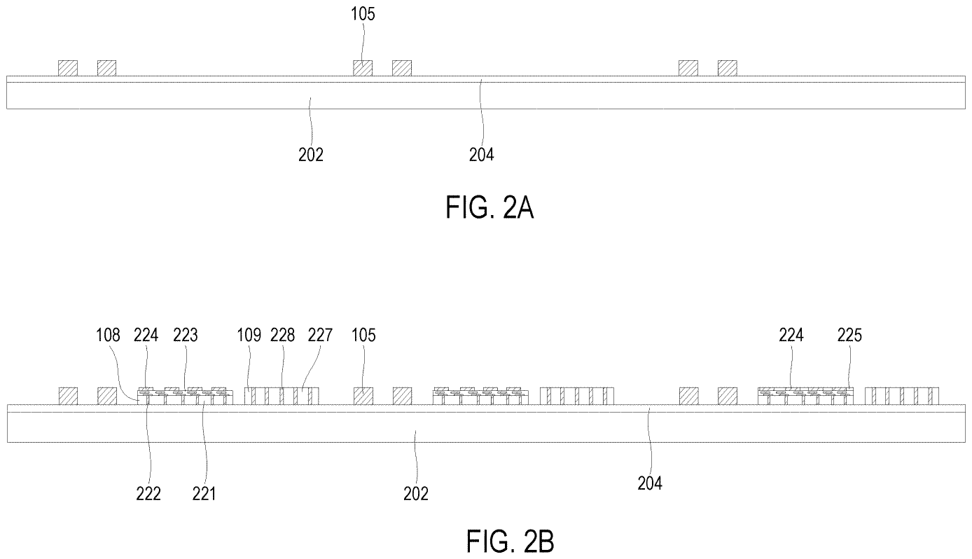

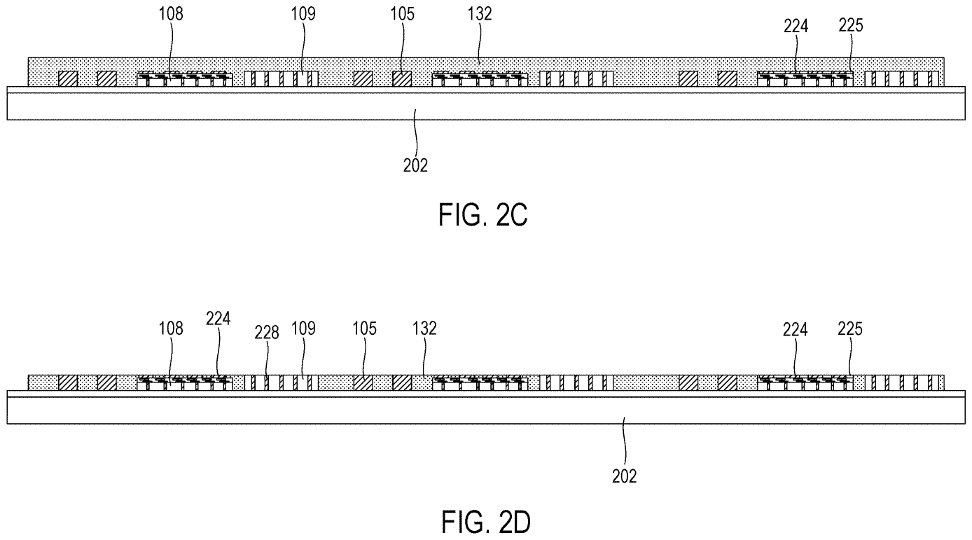

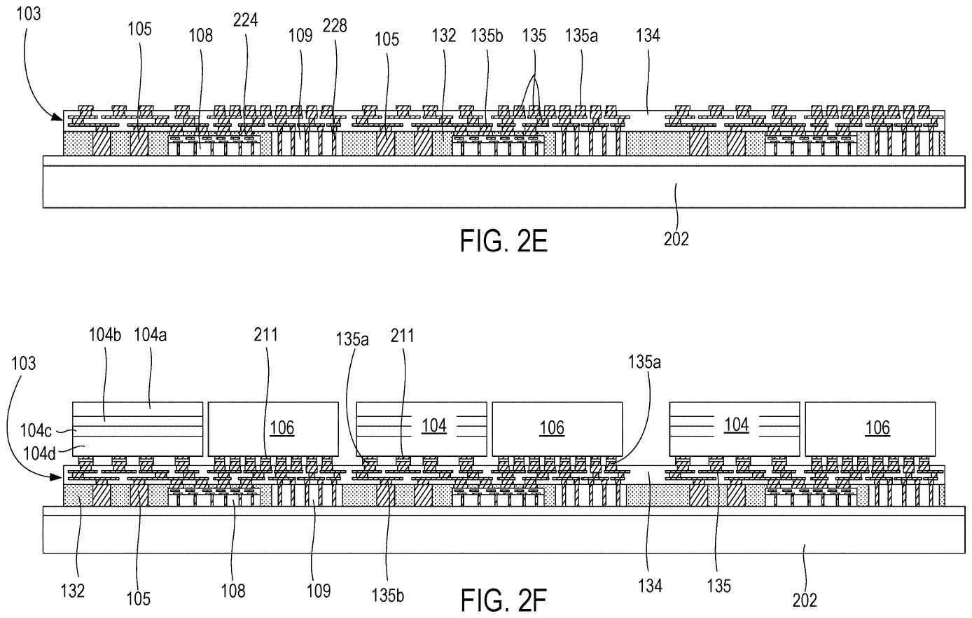

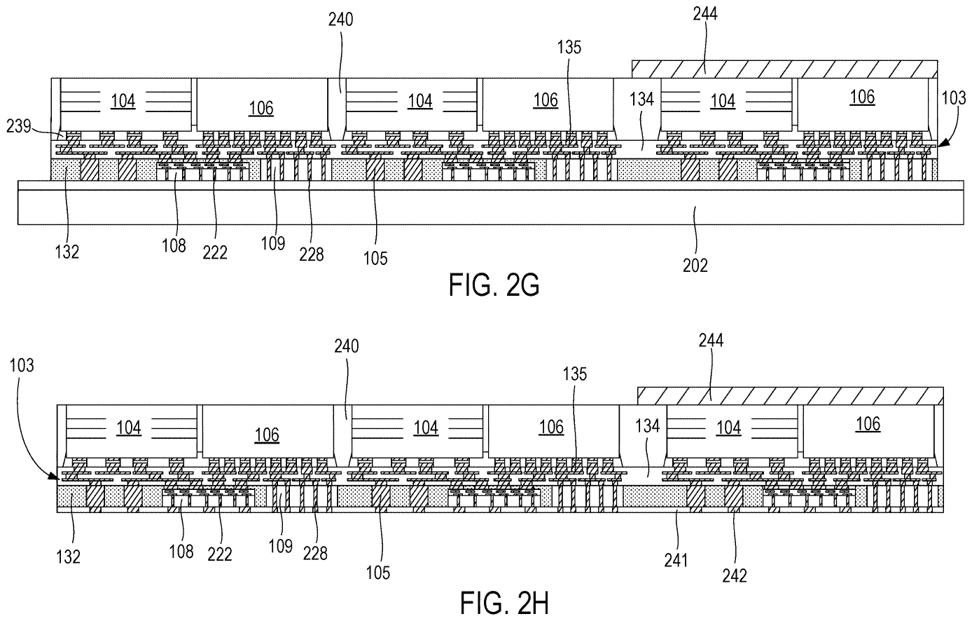

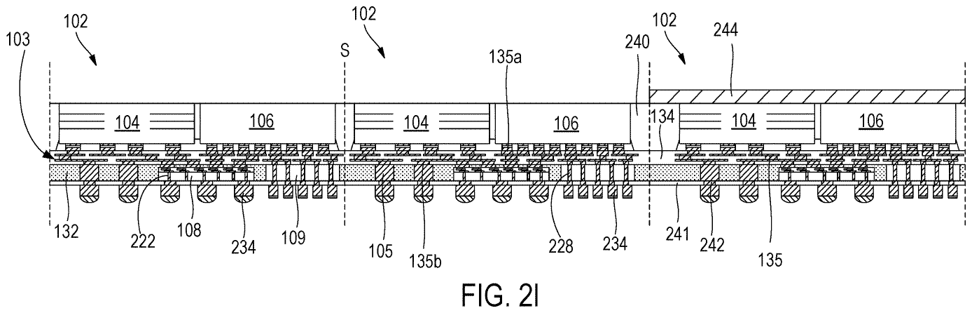

FIGS. 2A through 2I show an example method of making module 102 of electronic device 100 using cross-sectional views. The various steps in the example of FIGS. 2A through 2I can be performed in different orders, omitted, or along with additional steps or with variations suitable to make the various example electronic devices disclosed herein or other related examples. In accordance with various examples, module 112 and/or module(s) 10n (FIGS. 1A and 1B) can be fabricated using the example method of FIGS. 2A-2I.

FIG. 2A shows module 102 at an early stage of manufacture. In the example of FIG. 2A, multiple vertical interconnects 105 can be provided on a top side of carrier 202. In some examples, carrier 202 can include a temporary bond layer 204, which can be between or, in some examples, in contact with the lower ends of vertical interconnects 105.

In accordance with various examples, vertical interconnects 105 can be made of conductive material such as, for example, copper, gold, silver, palladium, or nickel. Vertical interconnects 105 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or ball drop. In some examples, a seed layer can be formed over temporary bond layer 204 on the top side of carrier 202, and then a mask pattern can be provided on a top side of the seed layer. Vertical interconnects 105 can be formed by plating over exposed portions of the seed layer. After vertical interconnects 105 are provided, the mask pattern(s) and portions of the seed layer not covered by vertical interconnects 105 can be removed.

Vertical interconnects 105 can be provided in rows and/or columns over carrier 202. In some examples, the height (i.e., thickness) of vertical interconnects 105 can range from approximately 800 μm to approximately 2000 μm. Vertical interconnects 105 can include or be referred to as vertical conductive structures such as pillars, posts, through mold vias (TMVs), copper core solder balls (CCBs), solder balls, or copper cube columns (CCCs). In accordance with various examples, CCCs can include a plurality of vertical conductive structures (e.g., columns, pillars, or posts) disposed in an insulating body, such as mold material (e.g., an epoxy mold compound, resin, or organic polymer with inorganic filler).

Carrier 202 can include a substantially planar top side. In some examples, carrier 202 can include or be referred to as a plate, board, wafer, panel, or support structure. For example, carrier 202 can be provided as a round wafer or square or rectangular panel. In some examples, the width of carrier 202 can range from approximately 100 millimeters (mm) to approximately 650 mm. Carrier 202 can serve to simultaneously handle multiple components in the process of providing module(s) 102. Temporary bond layer 204 can comprise or be referred to as a temporary bonding film, a temporary bonding tape, or a temporary adhesive coating. For example, temporary bond layer 204 can comprise a heat release tape (or film), an optical release tape (or film), a chemical release tape (or film), or a laser release tape (or film), wherein the adhesive strength of temporary bond layer 204 is weakened or removed by heat, light, chemical reaction, or laser energy, respectively. Temporary bond layer 204 can facilitate separation of modules 102 from carrier 202 at a later stage of manufacture. In some examples, physical force can be used solely or in addition to heat, light, chemical reaction, and/or laser energy to separate modules 102 from carrier 202.

FIG. 2B shows module 102 at later stage of manufacture. In the example shown in FIG. 2B, bridge die 108 and interconnect components 109 can be provided on temporary bond layer 204 over the top side of carrier 202. In some examples, the bridge die 108, interconnect components 109, and other electronic components can be picked up by pick-and-place equipment and placed on the top side of carrier 202. In some examples, the overall thickness of bridge die 108 can range from approximately 10 μm to approximately 800 μm, and the area of bridge die 108 can range from approximately 0.5 mm×0.5 mm to approximately 100 mm×100 mm.

In accordance with various examples, each of the one or more bridge die 108 can include bridge body 221, bridge through-interconnects 222, bridge signal distribution structure 223, and bridge upper interconnects 224. Bridge body 221 can comprise a semiconductor material (e.g., silicon, gallium arsenide (GaAs), indium phosphide (InP), etc.) or mold material that provides a bridge die top side, a bridge die bottom side, and bridge die lateral sides between the bridge die top side and the bridge die bottom side. Bridge through-interconnects 222 pass vertically through bridge body 221. In particular, an upper end of each bridge through-interconnect 222 can be exposed at the top side of bridge body 221. In some examples, the upper end of each bridge through-interconnect 222 can be coplanar with the top side of bridge body 221. Similarly, a lower end of each bridge through-interconnect 222 can be exposed at the bottom side of bridge body 221. In some examples, the lower end of each bridge through-interconnect 222 can be coplanar with the bottom side of bridge body 221.

In some examples, the bottom side of bridge die 108 can comprise one or more bridge lower dielectric layers. Bridge die 108 can include a silicon nitride (SiN) layer that covers the bottom side of bridge body 221. Further, bridge die 108 can include a polyimide (PI) layer that covers the bottom side of bridge body 221 and/or the SiN layer. In some examples, the lower end of each bridge through-interconnect 222 can be coplanar with the bottom side of the lowermost layer of the one or more bridge lower dielectric layers (e.g., the SiN layer or PI layer).

In some examples, each bridge through-interconnect 222 can have a width or diameter ranging from approximately 0.5 μm to approximately 200 μm. Moreover, the bridge through-interconnects 222 can be arranged with a pitch (i.e., spacing between adjacent bridge through-interconnects 222) ranging from approximately 0.5 μm to approximately 200 μm. In some examples, through-interconnects 222 can have a pitch of between 20 μm and 50 μm, between 25 μm and 35 μm, or of about 35 μm.

Bridge signal distribution structure 223 can be provided over, can be coupled to, and/or can cover the top side of bridge body 221. Further, bridge signal distribution structure 223 can be provided over, can be coupled to, and/or can cover the upper end of each bridge through-interconnect 222. In accordance with various examples, bridge signal distribution structure 223 can include a bridge dielectric structure and a bridge conductive structure. In some examples, the bridge signal distribution structure 223 can be formed during a back-end-of-line (BEOL) process.

The bridge dielectric structure can include one or more dielectric layers made of a dielectric or insulating material interleaved between conductive layers of the bridge conductive structure. In some examples, the bridge dielectric structure can include one or more layers of inorganic dielectric material such as SiO2, SiCN, or Si3N4. In some examples, the bridge dielectric structure can include one or more layers of organic dielectric material such as polyimide (PI), polymer, benzocyclobutene (BCB), polybenzoxazole (PBO), bismaleimide triazine (BT), Ajinomoto Buildup Film (ABF), or resin. The bridge dielectric structure can be provided by spin coating, spray coating, dip coating, rod coating, printing, oxidation, PVD, CVD, ALD, LPCVD, PECVD, and/or any other process known to one of ordinary skill in the art. In some examples, the thickness of the bridge dielectric structure can range from approximately 0.5 μm to approximately 50 μm, approximately 1.0 μm to approximately 15 μm, approximately 1.0 μm to approximately 5 μm, or approximately 1.0 μm to approximately 2 μm. In various examples, the thickness of bridge dielectric structure can refer to individual layers of bridge dielectric structure.

The bridge conductive structure can include one or more conductive layers defining signal distribution elements (e.g., traces, vias, pads, conductive paths, and/or UBMs) that are interleaved with dielectric layers of the bridge dielectric structure. The one or more conductive layers of the bridge conductive structure can include or be referred to as traces, pads, vias, conductive paths, wire patterns, circuit patterns, redistribution layers (RDLs), and/or UBM. In some examples, the bridge conductive structure can include copper, aluminum, iron, nickel, gold, silver, palladium, titanium, and/or tin. The bridge conductive structure can be provided by electrolytic plating, electroless plating, sputtering, deposition such as PVD, CVD, MOCVD, ALD, LPCVD, or PECVD. The bridge conductive structure can distribute electrical signals in a vertical direction and a lateral direction through the bridge signal distribution structure 223. In some examples, each conductive layer of the bridge conductive structure can have a thickness range from approximately 0.5 μm to approximately 20 μm, 1.0 μm to approximately 15 μm, approximately 1.0 μm to approximately 5 μm, or approximately 1.0 μm to approximately 2 μm. In some examples, the line width and the line spacing of the bridge conductive structure (i.e., the lateral width of individual traces of the bridge conductive structure and the lateral distance between adjacent traces of the bridge conductive structure) can be approximately 0.5 μm to approximately 20 μm, approximately 1.0 μm to approximately 10 μm, or approximately 2.0 μm to approximately 5.0 μm.

In some examples, the bridge conductive structure can provide conductive paths having a narrower width and/or a finer pitch than conductive paths provided by the conductive structure of redistribution structure 103 (FIG. 1B). In this manner, bridge signal distribution structure 223 can provide denser routing of signals than redistribution structure 103. By providing communication between electronic components, bridge signal distribution structure 223 can also reduce the number of layers in redistribution structure 103, which can simplify manufacturing, decrease costs, and improve yields.

In accordance with various examples, bridge upper interconnects 224 can be coupled to upper terminals of the bridge conductive structure. Bridge upper interconnects 224 can include or be referred to as pads, bumps, pillars, conductive posts, or solder balls. Bridge upper interconnects 224 can include conductive material such as aluminum, copper, an aluminum alloy, a copper alloy, solder, etc. In some examples, a bridge passivation 225 can be provided around bridge upper interconnects 224. Bridge passivation 225 can include a dielectric or electrically insulating material and can provide electrical insulation between bridge upper interconnects 224 and/or can protect bridge upper interconnects 224 from external environments. Bridge passivation 225 can surround bridge upper interconnects 224. Bridge passivation 225 can comprise or be referred to as a package body, an encapsulating structure, an insulator (e.g., polyimide (PI), polymer, etc.), a mold, an epoxy molding compound (EMC), a resin, a filler-reinforced polymer, a B-stage compressed film, gel, etc.

The bridge conductive structure of bridge signal distribution structure 223 can be coupled to bridge through-interconnects 222 and to bridge upper interconnects 224. The bridge conductive structure of bridge signal distribution structure 223 can electrically couple one or more of the bridge upper interconnects 224 to one or more of the bridge through-interconnects 222. In accordance with various examples, at least some of the bridge upper interconnects 224 are not electrically coupled to the bridge through-interconnects 222 and instead provide electrical connection between a first one of electronic components 104, 106, 110 (FIGS. 1A and 1B) and a second one of electronic components 104, 106, 110 (FIGS. 1A and 1B).

In some examples, interconnect components 109 can comprise structures similar to bridge die 108. In some examples, interconnect components 109 can comprise body 227. Body 227 can comprise a semiconductor material (e.g., silicon, gallium arsenide (GaAs), indium phosphide (InP)), glass, or mold material, for example. Conductive vias 228 can be formed through body 227 of interconnect component 109. Conductive vias 228 can comprise copper, aluminum, iron, nickel, gold, silver, palladium, titanium, tin, or other conductive materials. Conductive vias 228 can comprise a fine pitch (for example a pitch of 50 μm or less) to improve throughput of electronic signals through the volume of interconnect component 109, and/or to provide high density, narrow pitch interconnection to and from electronic component 106 (FIG. 2B). In some examples, the pitch of conductive vias 228 can be between approximately 20 μm and approximately 50 μm, between approximately 25 μm and approximately 35 μm, or approximately 35 μm.

In some examples, one or more additional electronic components can also be provided over carrier 202 and temporary bonding layer 204. In some examples, the electronic component can comprise a passive device (e.g., a capacitor, resistor, inductor, etc.). In some examples, the one or more electronic components includes a deep trench capacitor (DTC). In some examples, the one or more electronic components can comprise a dummy die, used for structural support and/or balancing coefficient of thermal expansion (CTE), and which does not include an electronical interconnection to any other components within module 102. In some examples, supplemental electronic components can comprise an active component (e.g., semiconductor die having an active (e.g., transistor) region or other integrated circuits).

Referring now to FIG. 2C, a cross-sectional view of module 102 at a later stage of manufacture is shown. In the example of FIG. 2C, mold material or encapsulant 132 can be provided to cover carrier 202, bridge die 108, interconnect components 109, and vertical interconnects 105. Encapsulant 132 can contact temporary bond layer 204 on the top side of carrier 202, the lateral sides or sidewalls of bridge die 108 and interconnect components 109, the top sides of bridge die 108 and interconnect components 109, the lateral sides or sidewalls of vertical interconnects 105, and the upper ends of vertical interconnects 105. In some examples, encapsulant 132 can be provided by compression molding, transfer molding, liquid body molding, vacuum lamination, paste printing, film-assisted molding, or any other suitable deposition process. Encapsulant 132 can comprise or be referred to as a package body, an encapsulating structure, an insulator, a mold, an epoxy molding compound (EMC), a resin, a filler-reinforced polymer, a B-stage compressed film, gel, etc.

Referring now to FIG. 2D, a cross-sectional view of module 102 at a later stage of manufacture is shown. In some examples, after encapsulant 132 is provided, an upper portion of encapsulant 132 can be removed to expose the upper ends of bridge upper interconnects 224, the upper ends of conductive vias 228, and the upper ends of vertical interconnects 105, as shown in FIG. 2D. For example, the upper portion of encapsulant 132 can be removed by grinding and/or chemical etching on the top side of encapsulant 132. In this regard, bridge upper interconnects 224, conductive vias 228, and/or vertical interconnects 105 can be exposed from the upper side of encapsulant 132. Encapsulant 132 can protect bridge die 108, interconnect components 109, and vertical interconnects 105 from external elements. In some examples, the upper side of encapsulant 132 can be coplanar with the upper sides of bridge upper interconnects 224, bridge passivation 225, conductive vias 228, and/or vertical interconnects 105.

FIG. 2E shows a cross-sectional view of module 102 at a later stage of manufacture. In the example shown in FIG. 2E, redistribution structure 103 can be provided over encapsulant 132, bridge die 108, interconnect component 109, vertical interconnects 105, and carrier 202. Redistribution structure 103 can be can cover, be coupled to, and/or contact encapsulant 132, bridge die 108, interconnect component 109, and vertical interconnects 105.

Redistribution structure 103 can include dielectric structure 134 and conductive structure 135. Conductive structure 135 can include upper terminals 135a and lower terminals 135b. In particular, providing dielectric structure 134 can include spin coating, spray coating, dip coating, rod coating, PVD, CVD, or any other suitable methods for forming an electrically insulating material such as polyimide (PI), benzocyclobutene (BCB), polybenzoxazole (PBO), resin, or Ajinomoto buildup film (ABF). Dielectric structure 134 can be over, can cover, or can be coupled to a top side of encapsulant 132, an upper end of each bridge upper interconnect 224, an upper side of interconnect component 109, and an upper end of each vertical interconnect 105. In some examples, after the lowermost (or first) layer of dielectric structure 134 is provided, openings exposing an upper end of each bridge upper interconnect 224, an upper end of each vertical interconnect 105, and openings exposing conductive vias 228 of interconnect component 109, can be provided. For example, after forming a mask pattern on the top side of the lowermost layer of dielectric structure 134, openings can be formed by removing exposed portions of the dielectric layer through etching. Portions of conductive structure 135 (e.g., lower terminals 135b) can then be provided in the openings, such that the portions of conductive structure 135 can couple to and/or can contact exposed upper ends of bridge upper interconnects 224 and exposed upper ends of vertical interconnects 105, and exposed conductive vias 228 of interconnect component 109.

Formation of redistribution structure 103 can include interleaving layers of conductive structure 135 with layers of dielectric structure 134. In accordance with various examples, conductive structure 135 can be provided by electrolytic plating, electroless plating, sputtering, PVD, CVD, MOCVD, ALD, LPCVD, PECVD, or any other suitable process for deposing metals such as copper, gold, silver, aluminum, nickel, palladium, titanium, tungsten, etc. In some examples, conductive structure 135 can be provided by plating. For example, a metal seed layer can be provided over exposed upper ends of bridge upper interconnects 224, over exposed upper ends of vertical interconnects 105, over exposed conductive vias 228 of interconnect component 109, and over a top side of a dielectric layer of dielectric structure 134. A mask pattern can be provided to cover the top side of the metal seed layer. A conductive layer of conductive structure 135 can then be provided through plating using exposed portions of the metal seed layer as a seed. After the conductive layer is formed, the mask pattern and exposed seed layer can be removed.

Conductive structure 135 can provide electrical signal paths (e.g., vertical paths and horizontal paths) through dielectric structure 134. Conductive structure 135 can be exposed at an inner (or upper) side of redistribution structure 103 and can comprise upper terminals 135a along the inner side of redistribution structure 103. Conductive structure 135 can also be exposed at an outer (or lower) side of redistribution structure 103 and can comprise lower terminals 135b along the outer side of redistribution structure 103. In some examples, lower terminals 135b can comprise or be referred to as pads, lands, vias, or UBM. In some examples, upper terminals 135a can comprise or be referred to as pads, lands, studs, or UBM. Lower terminals 135b can be coupled to and/or can contact bridge upper interconnects 224, upper ends of vertical interconnects 105, and conductive vias 228 of interconnect component 109. Layers and elements of conductive structure 135 can electrically couple upper terminals 135a with lower terminals 135b.

In some examples, redistribution structure 103 can comprise or be referred to as a redistribution layer (“RDL”) or build-up substrate. RDL substrates can comprise one or more conductive redistribution layers, for example layers of conductive structures 135, and one or more dielectric layers, for example layers of dielectric structure 134. The dielectric and conductive layers can be formed layer by layer over an electronic device to which the RDL substrate is coupled. In some examples, the dielectric and conductive layers can be formed layer by layer over a carrier that is at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly formed with one or more conductive layers that define respective conductive redistribution patterns or traces configured to collectively (a) fan-out electrical traces outside the footprint of the electronic device, or (b) fan-in electrical traces within the footprint of the electronic device.

In various examples, conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, which can interfere with the light from the photo-patterning process.

In some examples, such filler-free characteristics of filler-free dielectric materials can permit a reduction of the thickness of the resulting dielectric layer. Although the photo-definable dielectric materials described above can be organic materials, in other examples, the dielectric materials of the RDL substrates can comprise one or more inorganic dielectric layers. Some examples of inorganic dielectric layers can comprise silicon nitride (Si3N4), silicon oxide (SiO2), or silicon oxynitride (SiON). The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. RDL substrates can omit the permanent core or carrier structure generally associated with preformed, laminate substrates, as described below. Other substrates and signal distribution structures of this disclosure such as the bridge signal distribution structures 223 and/or base substrate 120 (FIG. 1B) can comprise RDL substrates.

FIG. 2F shows a cross-sectional view of module 102 at a later stage of manufacture. In the example shown in FIG. 2F, electronic components 104 and 106 can be provided over redistribution structure 103. In some examples, electronic component 104 can comprise memory die 104a, 104b, 104c stacked over controller die 104d. Each of electronic components 104 (e.g., 104a-104d) and 106 can include component interconnects 211 (e.g., bumps, Cu post, pillar, Cu post with solder caps, etc.).

Pick-and-place equipment can pick up electronic components 104 and 106 and place electronic components 104 and 106 on the top side of redistribution structure 103. Component interconnects 211 of each electronic component 104 and 106 can be positioned on a respective upper terminal 135a of conductive structure 135. Subsequently, component interconnects 211 can be bonded with their respective upper terminals 135a through a reflow process, a thermal compression process, a hybrid bonding process, or a laser assisted bonding process. Electronic components 110 (FIG. 1A) can be provided over redistribution structure 103 can coupled to upper terminals 135a in a similar manner.

In accordance with various examples, electronic components 104 and 106 (and 110 of FIG. 1A) can each comprise or be referred to as a die, chip, semiconductor package (e.g., multiple interconnected and/or stacked die and/or one or more die coupled to an interposer substrate), passive component, antenna patch, or power device. In some examples, one or more of electronic components 104 and 106 (and 110 of FIG. 1A) can comprise a digital signal processor (DSP), network processor, power management unit, audio processor, radio-frequency (RF) circuit, wireless baseband processor, system-on-chip (SoC) processor, memory, sensor, or application-specific integrated circuit (ASIC). In some examples, one or more of electronic components 104 and 106 (and 110 of FIG. 1A) can be configured to perform calculation and control processing, store data, or remove noise from electrical signals.

FIG. 2G shows a cross-sectional view of module 102 at a later stage of manufacture. In the example shown in FIG. 2G, underfill 239 can be provided between redistribution structure 103 and electronic components 104 and 106. In some examples, underfill 239 can span the lateral space between electronic components 104 and 106. Underfill 239 can comprise an electrically insulating material. In some examples, underfill 239 can be devoid of inorganic fillers. In some examples, underfill 239 can comprise or be referred to as a capillary underfill (CUF), a non-conductive paste (NCP), a non-conductive film (NCF), an anisotropic conductive film (ACF), or an anisotropic conductive paste (ACP)

As further shown in the example of FIG. 2G, encapsulant 240 can be provided to cover electronic components 104 and 106 and redistribution structure 103. Encapsulant 240 can contact a top side and sidewalls of electronic components 104 and 106, a top side of redistribution structure 103, and/or a sidewall of underfill 239. In some examples, elements, features, materials, or manufacturing methods of encapsulant 240 can be similar to those of encapsulant 132. Encapsulant 240 can protect electronic components 104 and 106 from external elements. In some examples, the underfill 239 can be omitted. In such examples, encapsulant 240, can underfill the space between redistribution structure 103 and electronic components 104 and 106, effectively replacing underfill 239. In such examples, encapsulant 240 can comprise or be referred to as molded underfill (MUF).

In some examples, after encapsulant 240 is provided, an upper portion of encapsulant 240 can be removed to thin module 102 or to expose the upper (or back) side of one or more of electronic components 104 and 106. For example, the upper portion of encapsulant 240 can be removed by grinding or chemical etching of the top side of encapsulant 240. The top side of encapsulant 240 can be coplanar with the top side of one or more of electronic components 104 and 106. In some examples, encapsulant 240 can remain over the top sides of electronic components 104 and 106 through the manufacture of module 102, and can be thinned after module 102 is bonded to base substrate 120 (FIG. 1B), as described in further detail below.

In some examples, a metallic structure 244 can be provided over electronic components 104 and 106 and encapsulant 240. Metallic structure 244 can be provided by plating in some examples. The materials, thickness, and location of metallic structure 244 can be selected to reduce or prevent warpage of module 102. In some examples, the thickness of metallic structure 244 can range from approximately 3.0 μm to approximately 35 μm, approximately 5.0 μm to approximately 25 μm, or approximately 5.0 μm to approximately 15 μm, or approximately 10.0 μm to approximately 15 μm.

In some examples, metallic structure 244 can comprise a multi-layer metal stack. For example, the metal layers can comprise an adhesion layer (e.g., Ti or TiW), a barrier layer (e.g., Ni or NiV) applied on the adhesion layer, a stiffener layer (e.g., Cu) applied on the barrier layer, and oxidation prevention or wetting layer (Ni, NiV, SUS, Au or Ag) applied on the stiffener layer. In some examples, the adhesion layer (e.g., Ti or TiW) and barrier layer (e.g., Ni or NiV) can be provided by sputtering and the barrier layer can be applied by plating. For example, after providing the adhesion and barrier layers, a Cu seed layer can be provided over the barrier layer, Cu can then be plated on the seed layer. In some examples, the thickness of the stiffener layer (e.g., the plated Cu) can be larger than the thickness of the adhesion and barrier layers. For example, the adhesion and barrier layers can each have a thickness of approximately 3 μm or less, or 1 μm or less, or 0.5 μm or less. The stiffener layer can have a thickness of 3 μm or greater, 5 μm or greater, or 10 μm or greater, and/or between 2 μm and 35 μm, between 5 μm and 25 μm, or between 10 μm and 15 μm. The thickness of the stiffener layer can be determined based on the desired CTE and warpage tendencies of the module 102. The oxidation prevention or wetting layer (Ni, NiV, SUS, Au, or Ag) can be applied over the plated stiffener layer by sputtering, plating, or any other desired metal deposition technique. The thickness of oxidation prevention or wetting layer can be less than the thickness of the plated stiffener layer. For example, the thickness of the oxidation prevention or wetting layer thickness can be approximately 3 μm or less, or 1 μm or less, or 0.5 μm or less.

FIG. 2H shows a cross-sectional view of module 102 at a later stage of manufacture. In the example shown in FIG. 2H, carrier 202 can be removed from the bottom side of bridge die 108, the bottom side of interconnect components 109, the lower ends of vertical interconnects 105, and the bottom side of encapsulant 132.

As a result of carrier 202 being removed, the bottom side of encapsulant 132, the lower ends of vertical interconnects 105, the bottom side of bridge die 108, and the bottom side of interconnect component 109 can be exposed. In some examples, the lower ends of bridge through-interconnects 222 and the lower ends of conductive vias 228 can be exposed after removal of carrier 202. In some examples, a die attach film (DAF) can be attached on the bottom side of interconnect component 109 and/or on the bottom side of bridge die 108, and removal of carrier 202 can expose the DAF.

As further shown at FIG. 2H, a lower passivation structure 241 and lower conductive structure 242 can be provided on the bottom side of bridge die 108, the bottom side of interconnect components 109, the bottom side of encapsulant 132, and the lower ends of vertical interconnects 105. In some examples, lower passivation structure 241 can comprise a dielectric material such as polymer, BT, PI, BCB, PBO, etc. Lower conductive structure 242 can include one or more layers of copper, aluminum, iron, nickel, gold, silver, palladium, titanium, tin, or other suitable electrically conductive material. In some examples, lower conductive structure 242 can comprise or be referred to as a UBM. Lower conductive structure 242 can be coupled to and/or can contact the lower ends of bridge through-interconnects 222, the lower ends of conductive vias 228, and the lower ends of vertical interconnects 105. In some examples, lower passivation structure 241 and lower conductive structure 242 can be provided as a multilayer interleaved structure similar to dielectric structure 134 and conductive structure 135 of redistribution structure 103.

FIG. 2I shows a cross-sectional view of module 102 at a later stage of manufacture. In the example shown in FIG. 2I, module interconnects 234 can be provided on the bottom side of lower conductive structure 242. In particular, module interconnects 234 can be provided such that module interconnects 234 are coupled to bridge through-interconnects 222, conductive vias 228, and vertical interconnects 105 via lower conductive structure 242. In some examples, module interconnects 234 can include tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, module interconnects 234 can be provided through a reflow process after forming a conductive material including solder on lower conductive structure 242 through a ball drop method. Module interconnects 234 can include or be referred to as conductive balls such as solder balls, conductive pillars such as copper pillars, or conductive posts having solder caps provided on copper pillars. In some examples, module interconnects 234 can be referred to as external input/output terminals of module 102. In some examples, module interconnects 234 can have varied pitch. For example, the pitch of module interconnects 234 coupled to conductive vias 228 can be less than the pitch of the module interconnects 234 coupled to vertical interconnects 105. In some examples, the pitch of module interconnects 234 coupled to conductive vias 228 can be 50 μm or less, 35 μm or less, between 20 μm and 35 μm, or approximately 35 μm, and the pitch of module interconnects 234 coupled to vertical interconnects 105 can be greater than 50 μm, 90 μm or greater, between 90 μm and 200 μm, or approximately 90 μm.

In the example shown in FIG. 2I, singulation can also be performed. In some examples, after providing module interconnects 234, a singulation process can be performed. In accordance with various examples, singulation can be performed by cutting through saw streets (indicated by lines S), for example, disposed around a perimeter of modules 102, thereby separating individual modules 102 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through encapsulant 240, redistribution structure 103, encapsulant 132, and/or lower passivation 241. After singulation, encapsulant 240, redistribution structure 103, encapsulant 132, and/or lower passivation 241 can be coplanar with one another.

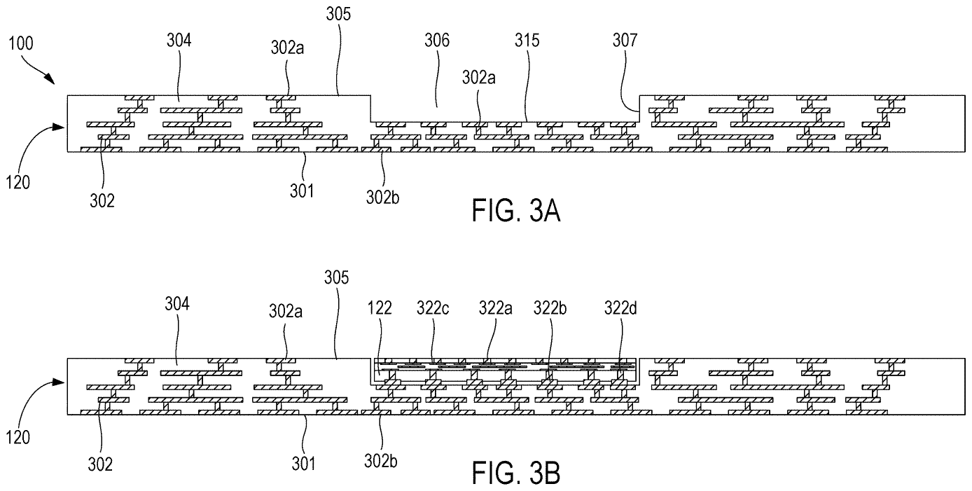

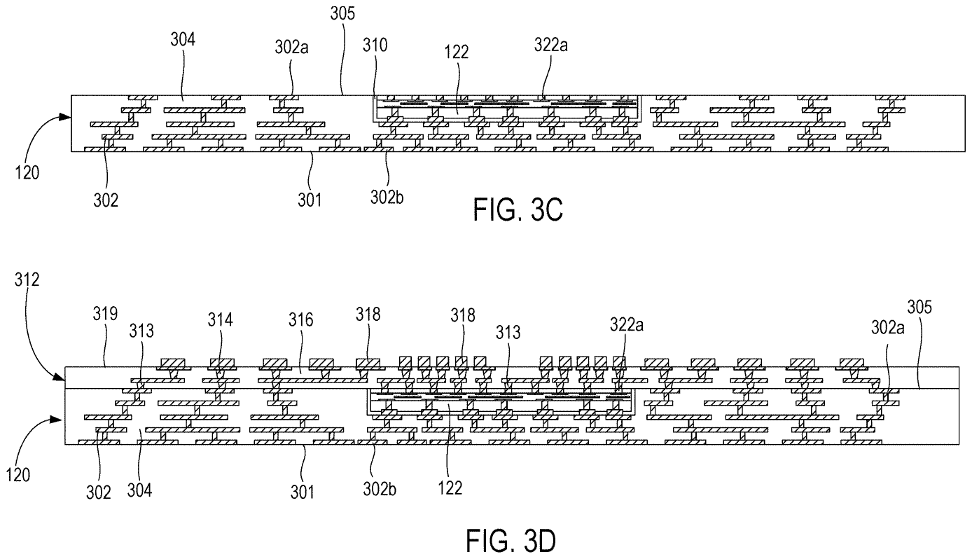

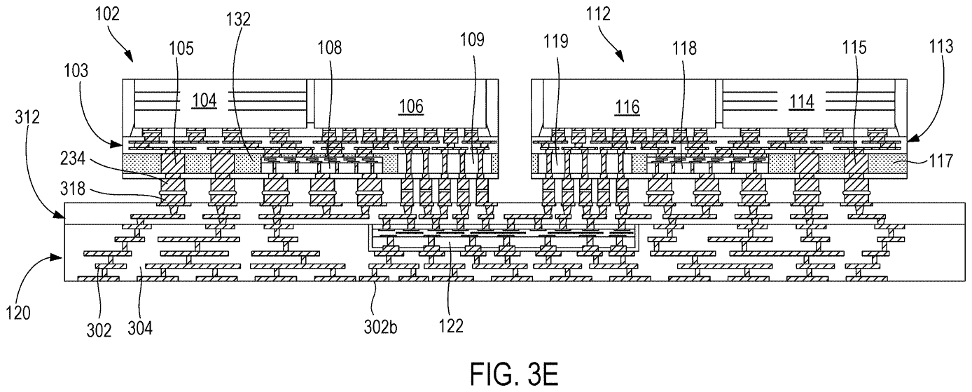

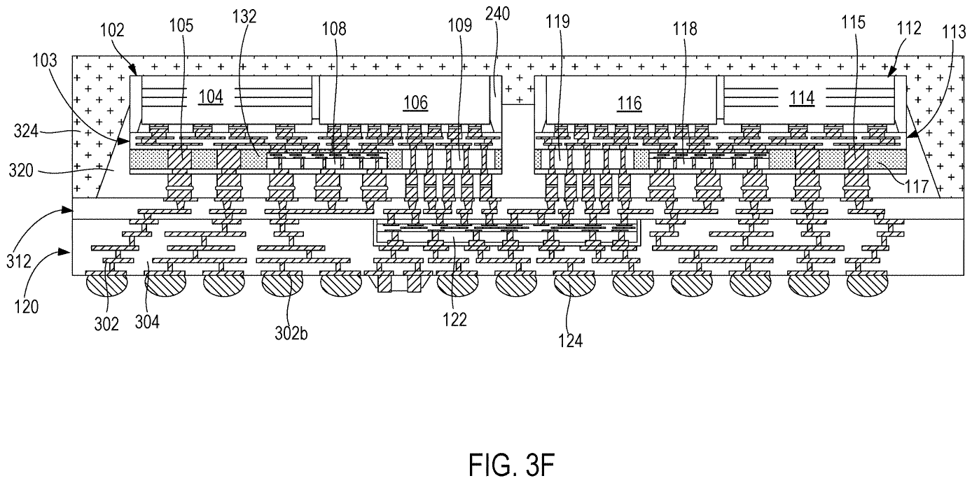

Referring now to FIGS. 3A-3F, an example method of manufacturing electronic device 100 is shown. Electronic device 100 can include multiple modules 102, 112 and/or 10n in some examples. FIG. 3A shows electronic device 100 at an early stage of manufacture. In the example of FIG. 3A, base substrate 120 can be provided. Base substrate 120 can comprise conductive structure 302 interleaved with dielectric structure 304.

In some examples, base substrate 120 can comprise or be referred to as a pre-formed or laminate substrate. Pre-formed substrates can be manufactured prior to attachment to an electronic component and can include dielectric layers between respective conductive layers. The conductive layers can include copper and can be formed using an electroplating process. The dielectric layers can be relatively thicker non-photo-definable layers; can be attached as a pre-formed film rather than as a liquid; and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can include a prepreg material or Ajinomoto Buildup Film (ABF). The pre-formed substrate can include a permanent core structure or carrier such as, for example, a dielectric material comprising bismaleimide triazine (BT) or FR4. In some examples, the permanent core structure can be glass. The dielectric and conductive layers can be formed on the permanent core structure. In other examples, the pre-formed substrate can be a coreless substrate and omit the permanent core structure, and the dielectric and conductive layers can be formed on a sacrificial carrier that is removed after formation of the dielectric and conductive layers and before attachment to the electronic component. The pre-formed substrate can be referred to as a printed circuit board (PCB) or a laminate substrate. Such pre-formed substrates can be formed through a semi-additive or modified-semi-additive process. Other substrates and signal distribution structures of this disclosure can include a pre-formed substrate.

In some examples, base substrate 120 can comprise structures or manufacturing techniques similar to those of redistribution structure 103 or other substrates described herein. In some examples, conductive structure 302 and dielectric structure 304 can comprise structures or manufacturing techniques similar to those described for conductive structure 135 and dielectric structure 134, respectively.

Base substrate 120 can comprise upper side 305 and lower side 301. A cavity 306 can be provided in upper side 305. Cavity 306 can be defined by and/or include sidewalls 307 and cavity floor 315. Cavity 306 can comprise a geometry suitable for receiving a bridge die. Terminals 302a of conductive structure 302 are disposed along upper side 305 and cavity floor 315. Terminals 302b of conductive structure 302 are disposed along lower side 301.

FIG. 3B shows electronic device 100 at a later stage of manufacture. In the example of FIG. 3B, bridge die 122 can be provided. Bridge die 122 can be provided in cavity 306 defined in base substrate 120. Bridge die 122 can be coupled to base substrate 120. The structures and manufacturing techniques of bridge die 122 can be similar to or the same as those of bridge 108.

In some examples, bridge die 122 can comprise interconnects 322a on an outer side and interconnects 322b on an inner side. In some examples, bridge die 122 can be referred to as a connection die or routing component. Bridge die 122 can transmit signals between adjacent modules 102. Bridge interconnects 322a and 322b of bridge die 122 can be provided to be spaced apart from each other in rows or columns. Bridge interconnects 322a and 322b can comprise or be referred to as pads, bumps, pillars, conductive posts, or solder balls. Bridge interconnects 322a and 322b can comprise conductive material such as aluminum, copper, an aluminum alloy, a copper alloy, solder, or other conductive materials.

In various examples, bridge die 122 can comprise a signal distribution structure 322c having a fine conductive pattern provided on the upper side of bridge die 122. It is contemplated and understood that signal distribution structure 322c can include multiple conductive layers or fine conductive patterns built-up over one another with interleaving dielectric layers. In some examples signal distribution structure 322c may be formed during a back-end-of-line (BEOL) process. For example, the dielectric layers of signal distribution structure 322c can comprise an inorganic dielectric material, such as, for example, silicon nitride (Si3N4), silicon oxide (SiO2), or silicon oxynitride (SiON). In some examples, the dielectric layers of signal distribution structure 322c can comprise an organic dielectric material, such as, for example, polyimide (PI), benzocyclobutene (BCB), polybenzoxazole (PBO), or Ajinomoto Buildup Film (ABF). The fine conductive pattern(s) of signal distribution structure 322c can electrically couple module 102 (FIG. 1A) to module 112 (FIG. 1B). In some examples, bridge die 122 can be devoid of active components (e.g., transistors) and can comprise only signal distribution structure 322c formed over the base material of bridge die 122. In some examples, bridge die 122 can comprise a semiconductor material such as silicon. In some examples, bridge die 122 can comprise a mold material, ceramic, or glass. In the example of FIG. 3B, bridge interconnects 322a can be coupled to signal distribution structure 322c.

In various examples, bridge die 122 can comprise through interconnects 322d. Through interconnects 322d can penetrate bridge die 122 and couple interconnects 322b along the lower side of bridge die 122 to one or more of the bridge interconnects 322a located along the upper side of bridge die 122. For example, through interconnects 322d can couple interconnects 322b to signal distribution structure 322c. The central portion (e.g., the base material) of bridge die 122 can comprise a semiconductor material, mold material, ceramic, or glass through which the through interconnects 322d extend.

In some examples, bridge die 122 can comprise a backside signal distribution structure on the same side of bridge die 122 as lower interconnects 322b. The backside signal distribution structure can be similar to signal distribution structure 322c. For example, the backside signal distribution structure can comprise one or more conductive layers interleaved with one or more dielectric layers. Through interconnects 322d can electrically couple the backside signal distribution structure to signal distribution structure 322c. Interconnects 322b can be coupled to the lower side of the backside signal distribution structure. In this regard, a backside signal distribution structure can electrically couple one or more of interconnects 322b to through interconnects 322d. In some examples, the dielectric layers of a backside signal distribution structure can be similar to the dielectric layers of signal distribution structure 322c (e.g., both the backside signal distribution structure and signal distribution structure 322c can include inorganic or organic dielectric layers). In some examples, the dielectric layers of the backside signal distribution structure can comprise organic dielectric material, and the dielectric layers of signal distribution structure 322c can comprise inorganic dielectric material. In some examples, bridge die 122 includes a bridge passivation around bridge interconnects 322a, similar to bridge passivation 225 of bridge die 108 in FIG. 2B.

FIG. 3C shows electronic device 100 at a later stage of manufacture. In the example of FIG. 3C, encapsulant 310 can be provided. Encapsulant 310 can be provided around the lateral sides of bridge die 122. Encapsulant 310 can comprise or be referred to as a package body, an encapsulant, an encapsulating structure, a mold, an underfill, an epoxy molding compound, a resin, a filler-reinforced polymer, a B-stage compressed film, or a gel. Encapsulant 310 can be provided by transfer molding, compression molding, liquid encapsulant molding, vacuum lamination, paste printing, film assisted molding, or other suitable processes. In some examples, encapsulant 310 can be disposed between bridge die 122 and cavity floor 315 and sidewalls 307 of base substrate 120. Encapsulant 310 can contact or cover the side walls and lower side of bridge die 122. The upper sides of bridge interconnects 322a can be exposed from encapsulant 310. Encapsulant 310 can protect bridge die 122 from the external environment or from environmental exposure.

FIG. 3D shows electronic device 100 at a later stage of manufacture. In the example of FIG. 3D, redistribution structure 312 can be provided over bridge die 122 and base substrate 120. Redistribution structure 312 can be provided over the upper sides of encapsulant 310, base substrate 120, and bridge die 122.

Redistribution structure 312 includes conductive structure 314 and dielectric structure 316. The elements or layers of conductive structure 314 can interleaved with the layers or elements of dielectric structure 316. In some examples, redistribution structure 312 can be an RDL substrate, as previously described. In some examples, redistribution structure 312 can comprise a pre-formed substrate, as previously described.

In various examples, terminals 318 of redistribution structure 312 can be provided along an upper side 319 of redistribution structure 312. Terminals 318 can comprise or be referred to as pads, lands, UBMs (Under Bump Metals), studs, bumps, or pillars. Terminals 318 can be coupled to or included in conductive structure 314. Terminals 313 of redistribution structure 312 can be provided along a lower side of redistribution structure 312. Terminals 313 can be coupled to and/or can contact terminals 302a of conductive structure 302 and bridge interconnects 322a of bridge die 122. A device substrate can comprise a combination of redistribution structure 312, base substrate 120, or components embedded therein.

FIG. 3E shows electronic device 100 at a later stage of manufacture. In the example of FIG. 3E, module 102 and module 112 can be coupled to redistribution structure 312. Module 112 can comprise structures or manufacturing techniques similar to those of module 102. Module interconnects 234 can be coupled to terminals 318 of redistribution structure 312 by thermocompression bonding, reflow, ultrasonic bonding, or laser assisted bonding. Module 102 can be in electronic communication with module 112 across bridge die 122. In particular, electronic component 106 of module 102 can be in electronic communication with electronic component 116 of module 112 via redistribution structure 103 and interconnect component 109 of module 102, redistribution structure 312 and bridge die 122 of base substrate 120, and interconnect component 119 and redistribution structure 113 of module 112.

Forming redistribution structure 312 over base substrate 120, and particularly, forming an RDL substrate over base substrate 120 can allow for terminals 318 of redistribution structure 312 to be formed with narrow and varied pitch. For example, the pitch of terminals 318 can match the varied pitch of module interconnects 234. Redistribution structure 312 can also compensate for any misalignment that can occur during placement or encapsulating of bridge 122.

FIG. 3F shows electronic device 100 at a later stage of manufacture. In the example of FIG. 3F, underfill 320 can be provided. Underfill 320 can be between module 102 and redistribution structure 312 and between module 112 and redistribution structure 312. Underfill 320 can extend over and in some examples completely cover the lateral sides of modules 102 and 112. In some examples, underfill 320 can extend from module 102 to module 112 and/or fill the volume between module 102 and module 112.

In accordance with various examples, underfill 320 can comprise or be referred to as capillary underfill, non-conductive paste, or non-conductive film. In some examples, underfill 320 can be urged into a gap between modules 102 and 112 and redistribution structure 312 after modules 102 and 112 are electrically coupled to redistribution structure 312. In some examples, underfill 320 can be pre-coated onto substrate redistribution structure 312 prior to modules 102 and 112 being coupled to redistribution structure 312. In some examples, underfill 320 can be pre-coated on modules 102 and 112 prior to coupling to redistribution structure 312. In some examples, a curing process (e.g., a thermal curing process or a photocuring process) can be performed on underfill 320. In some examples, underfill 320 can be provided using materials and techniques similar to those of encapsulant 310.

In some examples, encapsulant 324 can be provided over underfill 320, redistribution structure 312, and modules 102 and 112. Encapsulant 324 can comprise structures or manufacturing techniques similar to those of encapsulant 240. In some examples, an upper portion of encapsulant 324 can be removed to electronic device 100. For example, the upper portion of encapsulant 324 can be removed by grinding or chemical etching of the top side of encapsulant 324. In some examples, a portion of encapsulant 240 located over electronic component 104 and/or electronic component 106 can be removed along with encapsulant 324. Removal of encapsulant 240 can expose the upper (or back) side of one or more of electronic components 104 and 106. In some examples, encapsulant 324 can be coplanar with encapsulant 240 and/or the backsides of electronic component 104 and/or electronic component 106 Removing encapsulant 240 after coupling modules 102 and 112 to base substrate 120 can reduce or prevent warpage of modules 102 and 112 and/or of base substrate 120. For example, having an increased volume of encapsulant 240 on modules 102 and 112 during bonding of module interconnects 234 to terminals 318 can stiffen modules 102 and 112 thereby preventing or reducing warpage. Reduced warpage can increase the reliability of the electrical interconnection between modules 102 and 112 and base substrate 120. For example, reduced warpage can decrease occurrences of interconnection failure between module interconnects 234 and terminals 318 of redistribution structure 312, and/or between external interconnects 124 and a next level device (e.g., a PCB to which electronic device 100 can be subsequently coupled).

In the example shown in FIG. 3F, external interconnects 124 can be provided on the bottom side of conductive structure 302. In particular, external interconnects 124 can be provided on terminals 302b of conductive structure 302. In some examples, external interconnects 124 can include tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 124 can be provided through a reflow process after forming a conductive material including solder on terminals 302b through a ball drop method. External interconnects 124 can include or be referred to as conductive balls such as solder balls, conductive pillars such as copper pillars, or conductive posts having solder caps provided on copper pillars. In some examples, external interconnects 124 can be referred to as external input/output terminals of electronic device 100.

In some examples, after providing external interconnects 124, a singulation process can be performed. In accordance with various examples, singulation can be performed by cutting through saw streets disposed around a perimeter of electronic devices 100, thereby separating electronic devices 100 from one another.

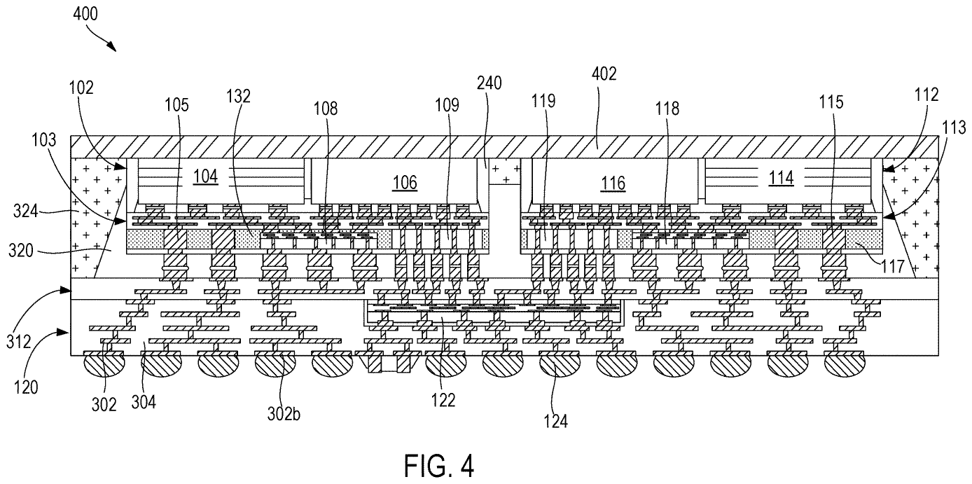

Referring now to FIG. 4, example electronic device 400 is shown, in accordance with various examples. Electronic device 400 can comprise structures or manufacturing techniques similar to those of electronic device 100 or other electronic devices described herein. Electronic device 400 can be made by removing a portion of encapsulant 324 to expose an upper side of modules 102 and 112. Backside metallization (BSM) 402 can be provided. BSM 402 can be provided over encapsulant 324 and over the exposed sides of modules 102 and 112. Various examples can similarly include a heat spreader, stiffener, lid, or other additional structures coupled to the outer side of modules 102 and 112 or encapsulant 324. The structures or manufacturing techniques of BSM 402 can be similar to or the same as those of metallic structure 244 in FIG. 2H.

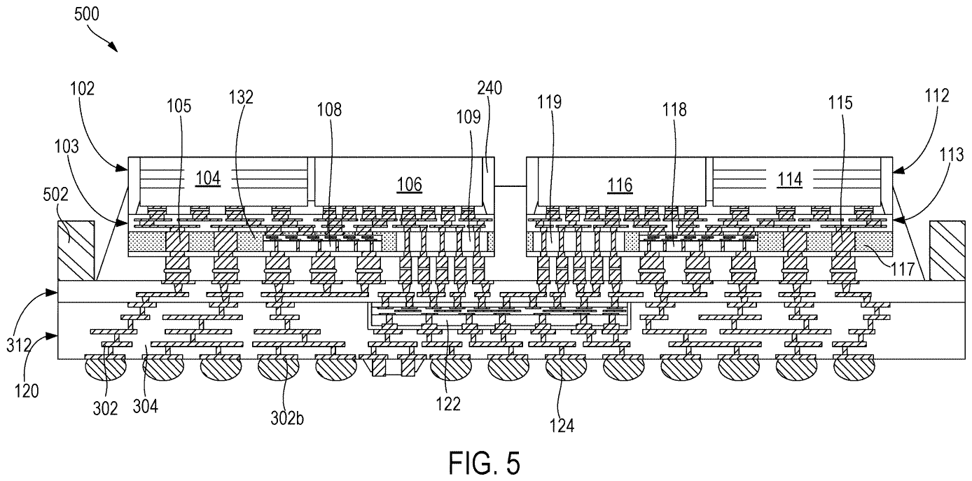

Referring now to FIG. 5, example electronic device 500 is shown. Electronic device 500 can comprise structures or manufacturing techniques similar to those of electronic device 100 or other electronic devices described herein. Electronic device 500 can omit encapsulant 324 in some examples. Stiffener 502 can be coupled to redistribution structure 312 over base substrate 120. Stiffener 502 can be disposed around a perimeter of modules 102 and 112 (and module 10n FIG. 1A) and underfill 320. Stiffener 502 can be coupled to an outer side of redistribution structure 312. For example, Stiffener 502 can be coupled to a side of redistribution structure 312 opposite (i.e., oriented away from) base substrate 120. In some examples, an adhesive can couple stiffener 502 to redistribution structure 312. Stiffener 502 can comprise a metal, metal alloy, ceramic, glass, or any other suitable material. Upper sides of modules 102 and 112 can be exposed from underfill 320.

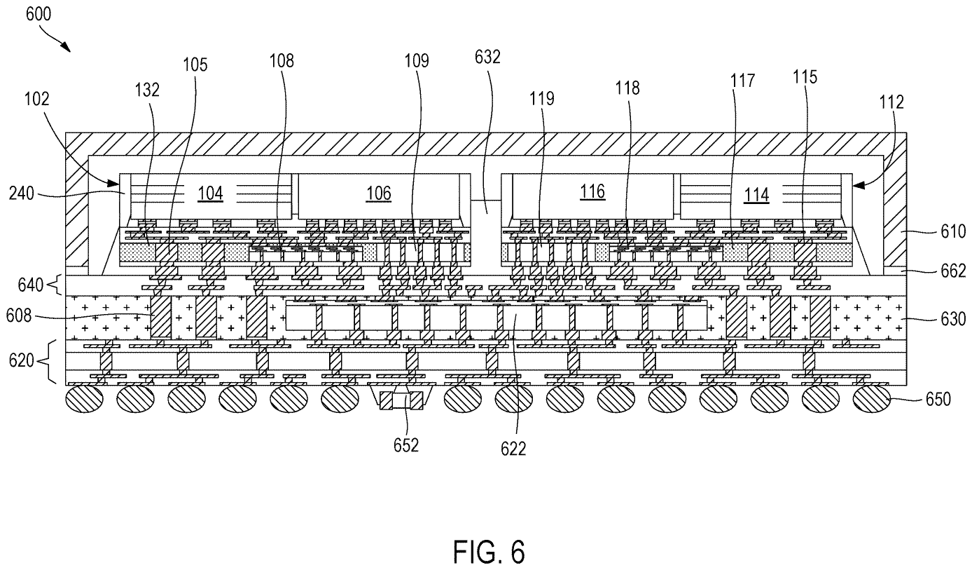

With reference to FIG. 6, electronic device 600 is shown, in accordance with various examples. Structures or manufacturing techniques of electronic device 600 can be similar to those of electronic device 100 or other electronic devices described herein. In the example of FIG. 6, electronic device 600 comprises modules 102 and 112 in communication through bridge die 622. In accordance with various examples, electronic device 600 can further include one or more modules 10n, similar to electronic device 100 in FIG. 1A, which can be coupled to one another and/or to module 102 and/or module 112 via additional bridge die 622.

In various examples, modules 102 and 112 are coupled to redistribution structure 640. Redistribution structure 640 can be over vertical interconnects 608, bridge die 622, and encapsulant 630. Bridge die 622, vertical interconnects 608, and encapsulant 630 are over an inner side of base substrate 620. External interconnects 650 can be coupled to an outer side of base substrate 620. Lid 660 can be coupled to redistribution structure 640 by adhesive 662.

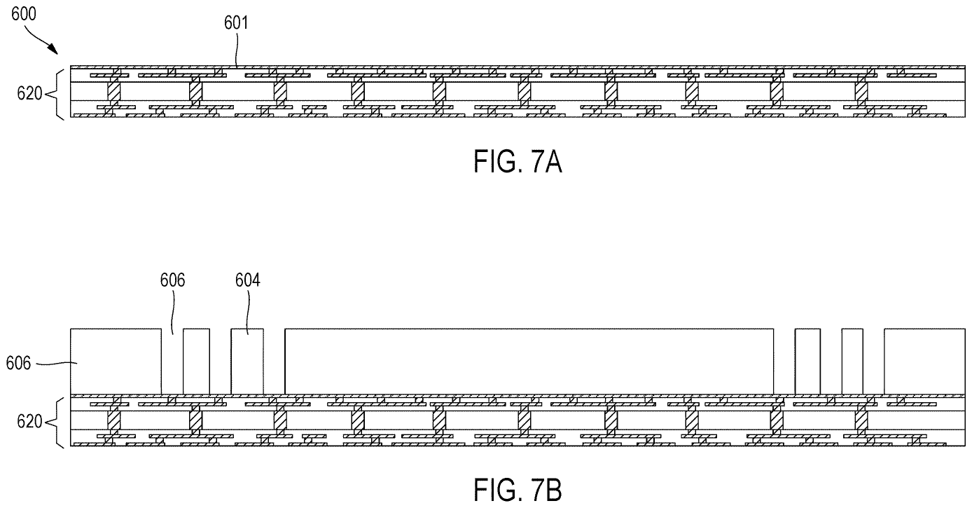

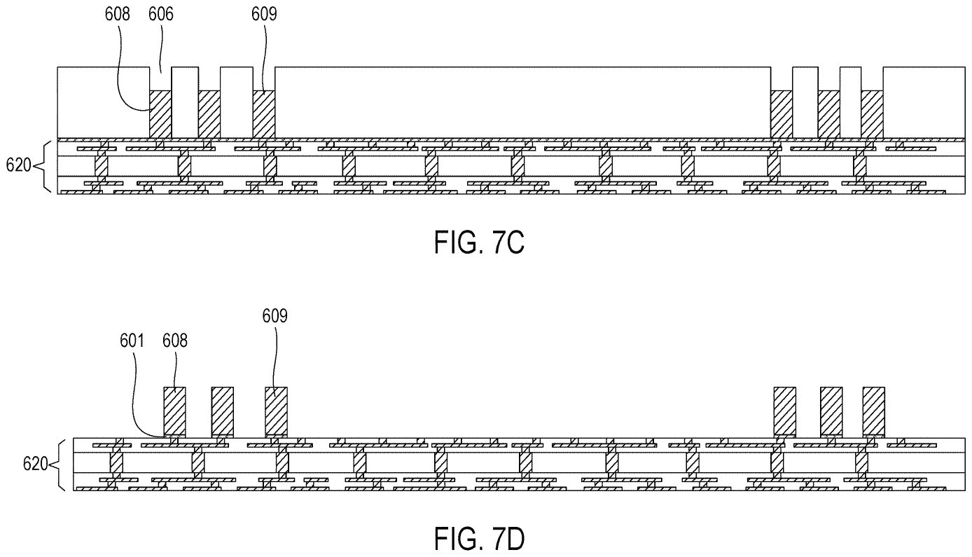

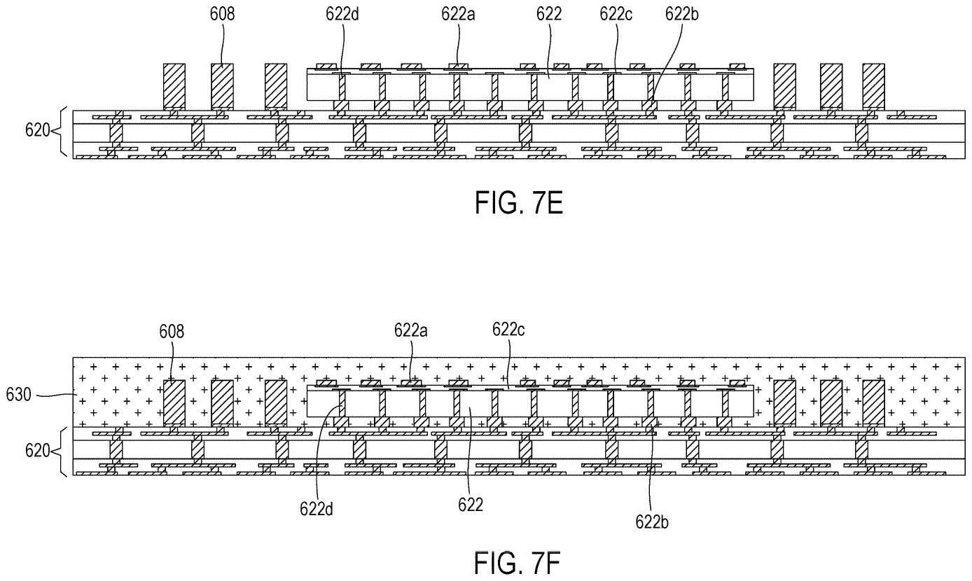

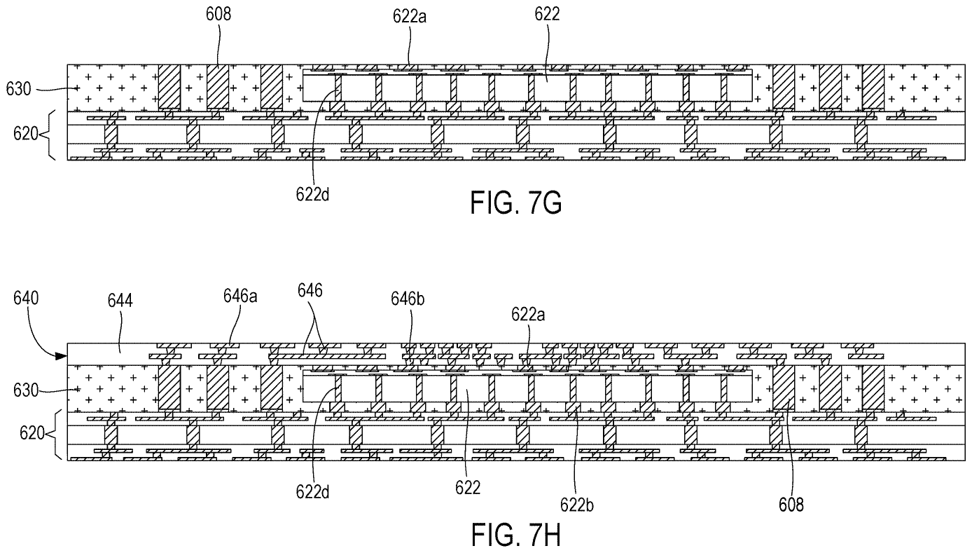

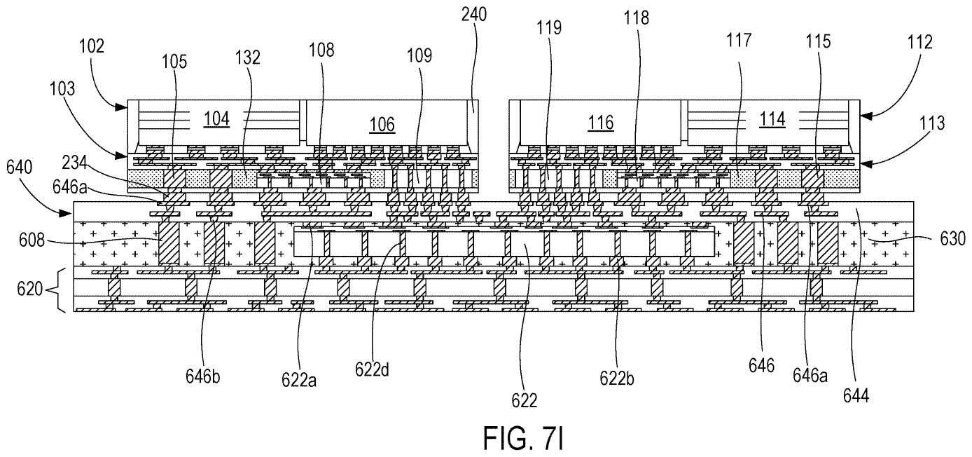

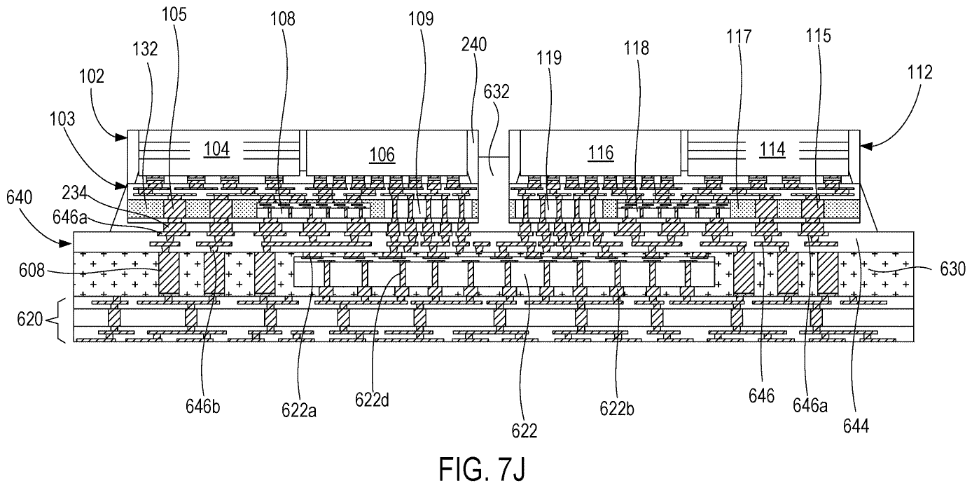

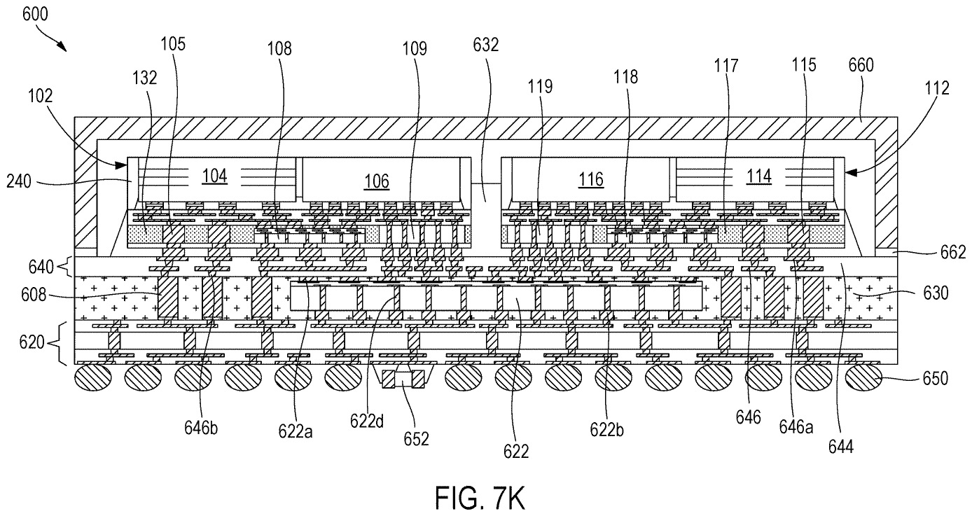

Referring now to FIGS. 7A-7K, a method of manufacturing electronic device 600 is shown, in accordance with various examples. FIG. 7A shows electronic device 600 at an early stage of manufacture. In the example of FIG. 7A, substrate 620 can be provided. Substrate 620 can comprise structures or manufacturing techniques similar to those of base substrate 120 or other substrates described herein. In some examples, substrate 620 can be a pre-formed substrate, as previously described. In some examples, substrate 620 can be an RDL substrate, as previously described.

Seed 601 can be provided over substrate 620. Seed 601 can be formed by electroless plating, electrolytic plating, sputtering, PVD, CVD, MOCVD, ALD, LPCVD, PECVD, or any other suitable deposition process. Seed 601 can comprise titanium (Ti) or titanium tungsten (TiW), copper (Cu), aluminum (Al), nickel (Ni), gold (Au), or silver (Ag). In some examples, the thickness of seed 601 can range from about 0.01 μm to about 1 μm. In some examples, seed 601 can comprise multiple layers.

FIG. 7B shows electronic device 600 at a later stage of manufacture. In the example of FIG. 7B, pattern 604 can be provided over seed 601. Pattern 604 can comprise a photoresist or mask in some examples. Pattern 604 can be provided over seed 601 and can be patterned using various techniques such as, for example, exposure, development, etching, or curing to form openings 606. Openings 606 can expose portions of seed 601.

FIG. 7C shows electronic device 600 at a later stage of manufacture. In the example of FIG. 7C, conductive material 609 can be provided in openings 606. Conductive material 609 can be provided on seed 601. Conductive material 609 can be located in, fill, or partially fill openings 606 to form vertical interconnect 608. Vertical interconnect 608 can comprise or be referred to as conductive vias, posts, pins, pillars, or other vertical interconnects in some examples. Electrically conductive material 609 can be provided by electroless plating, electrolytic plating, sputtering, PVD, CVD, MOCVD, ALD, LPCVD, PECVD, or using other suitable deposition techniques. Electrically conductive material 609 can comprise metals (e.g., Cu, Al, Au, Ag, or Ni), alloys, compounds, or other conductive materials.

FIG. 7D shows electronic device 600 at a later stage of manufacture. In the example of FIG. 7D, pattern 604 can be removed. Vertical interconnects 608 can remain over substrate 620 with portions of seed 601 covered by conductive material 609 and portions of seed 601 exposed from conductive material 609 removed from over substrate 620.

In various examples, vertical interconnects 608 can be electrically isolated from one another in response to removal of exposed portions of seed 601. In some examples, exposed portions of seed 601 can be removed through etching (e.g., wet etching or dry etching). Remaining portions of seed 601 can comprise part of vertical interconnects 608. While vertical interconnects 608 are shown as being plated in the example of FIGS. 7B-7D, it is contemplated and understood that in other examples, vertical interconnects can comprise pre-formed structures (e.g., Cu pins, solder coated copper core balls, solder coated copper core pins, etc.) that are placed on and subsequently bonded to base substrate 620.

FIG. 7E shows electronic device 600 at a later stage of manufacture. In the example of FIG. 7E, bridge die 622 can be provided over base substrate 620. Bridge die 622 can be coupled to substrate 620 between vertical interconnects 608. Vertical interconnects 608 can be disposed around the lateral sides of bridge die 622.

In various examples, bridge die 622 can comprise interconnects 622a on an outer side and interconnects 622b on an inner side. In some examples, bridge die 622 can be referred to as a connection die or routing component. With brief reference to FIG. 6, bridge die 622 can transmit signals between module 102 and module 112. In some examples, bridge die 622 can transmit signals between the upper redistribution structure 640 and base substrate 620. Returning to FIG. 7E, bridge interconnects 622a and 622b of bridge die 622 can be provided to be spaced apart from each other in a row and/or column direction. Bridge interconnects 622a and 622b can comprise or be referred to as pads, bumps, pillars, conductive posts, or solder balls. Bridge interconnects 622a and 622b can comprise conductive material such as aluminum, copper, an aluminum alloy, a copper alloy, solder, etc.

Bridge die 622 comprises a signal distribution structure 622c having a fine conductive pattern provided on the upper side of bridge die 622. It is contemplated and understood that signal distribution structure 622c can include multiple conductive layers and/or fine conductive patterns built-up over one another with interleaving dielectric layers. In some examples, signal distribution structure 622c may be formed during a back-end-of-line (BEOL) process. For example, the dielectric layers of signal distribution structure 622c can comprise an inorganic dielectric material, such as, for example, silicon nitride (Si3N4), silicon oxide (SiO2), and/or silicon oxynitride (SiON). In some examples, the dielectric layers of signal distribution structure 622c can comprise an organic dielectric material, such as, for example, polyimide (PI), benzocyclobutene (BCB), polybenzoxazole (PBO), or Ajinomoto Buildup Film (ABF). The fine conductive pattern(s) of the signal distribution structure 622c can electrically couple module 102 (FIG. 6) to module 112 (FIG. 6). In some examples, bridge die 622 can be devoid of active components (e.g., transistors) and can comprise only the signal distribution structure 622c formed over the base material of the bridge die 622. In some examples, bridge die 622 can comprise a semiconductor material such as silicon. In some examples, bridge die 622 can comprise a mold material, ceramic, or glass. In the example of FIG. 7E, bridge interconnects 622a can be coupled to signal distribution structure 622c.

In various examples, bridge die 622 can comprise through interconnects 622d. Through interconnects 622d can penetrate bridge die 622 and couple interconnects 622b along the lower side of bridge die 622 to one or more of the bridge interconnects 622a located along the upper side of bridge die 622. For example, through interconnects 622d can couple interconnects 622b to the signal distribution structure 622c. The central portion (e.g., the base material) of bridge die 622 can comprise a semiconductor material, mold material, ceramic, or glass through which the through interconnects 622d pass.

In some examples, bridge die 622 can comprise a backside signal distribution structure on the same side of bridge die 622 as lower interconnects 622b. The backside signal distribution structure can be similar to signal distribution structure 622c. For example, the backside signal distribution structure can comprise one or more conductive layers interleaved with one or more dielectric layers. Through interconnects 622d can electrically couple the backside signal distribution structure to signal distribution structure 622c. The interconnects 622b can be coupled to the lower side of the backside signal distribution structure. In this regard, a backside signal distribution structure can electrically couple one or more of the interconnects 622b to through interconnects 622d. In some examples, the dielectric layers of a backside signal distribution structure can be similar to the dielectric layers of signal distribution structure 622c (e.g., both the backside signal distribution structure and signal distribution structure 622c can include inorganic or organic dielectric layers). In some examples, the dielectric layers of the backside signal distribution structure can comprise organic dielectric material, and the dielectric layers of signal distribution structure 622c can comprise inorganic dielectric material. In some examples, bridge die 622 can include a bridge passivation, similar to bridge passivation 225 of bridge die 108 in FIG. 2B. The bridge passivation surround bridge interconnects 622a.

FIG. 7F shows electronic device 600 at a later stage of manufacture. In the example of FIG. 7F, encapsulant 630 can be provided. Encapsulant 630 can be provided around the lateral sides of and over vertical interconnects 608 and bridge die 622. Encapsulant 630 can comprise or be referred to as a package body, encapsulant, encapsulating structure, mold, epoxy molding compound, resin, filler-reinforced polymer, B-stage compressed film, or gel. Encapsulant 630 can be provided by transfer molding, compression molding, liquid encapsulant molding, vacuum lamination, paste printing, film assisted molding, or other suitable processes. In some examples, encapsulant 630 can contact or cover a bottom side or lateral side of bridge die 622. Encapsulant 630 can protect bridge die 622 from the external environment or from environmental exposure.

FIG. 7G shows electronic device 600 at a later stage of manufacture. In the example of FIG. 7G, a portion of encapsulant 630 can be removed from an outer side of electronic device 600. A portion of encapsulant 630 can be removed to expose the upper sides of vertical interconnects 608 and interconnects 622a of bridge die 622. In some examples, a back grinding or chemical mechanical polish (CMP) can be used to remove a portion of encapsulant 630 and a portion of vertical interconnects 608. The outer side of encapsulant 630, vertical interconnects 608, and interconnects 622a can be coplanar after the removal step.

FIG. 7H shows electronic device 600 at a later stage of manufacture. In the example of FIG. 7H, redistribution structure 640 can be provided. Redistribution structure 640 can be provided over the coplanar sides of encapsulant 630, vertical interconnects 608, and interconnects 622a of bridge die 622.

In accordance with various examples, redistribution structure 640 includes dielectric structure 644 and conductive structure 646. Elements or layers of conductive structure 646 can be interleaved with elements or layers of dielectric structure 644. In some examples, redistribution structure 640 can be an RDL substrate, as previously described. In some examples, redistribution structure 640 can comprise a pre-formed substrate, as previously described.

In accordance with various examples, conductive structure 646 includes inner terminals 646a located along an inner side of redistribution structure 640. Inner terminals 646a can comprise or be referred to as pads, lands, UBMs (Under Bump Metals), studs, bumps, or pillars. Conductive structure 646 further includes outer terminals 646b located at an outer side of redistribution structure 640. Outer terminals 646b can comprise or be referred to as vias, pads, lands, UBMs (Under Bump Metals), studs, bumps, or pillars. Outer terminals 646b can be coupled to and/or can contact vertical interconnects 608 and interconnects 622a of bridge die 622.

Forming redistribution structure 640, and particularly, forming an RDL substrate over bridge die 622 and vertical interconnects 608 can allow for inner terminals 646a of redistribution structure 640 to be formed with narrow and varied pitch. For example, the pitch of inner terminals 646a can match the varied pitch of module interconnects 234 (FIG. 7I). Forming redistribution structure 640 can also compensate for any misalignment that can occur during placement or encapsulating of bridge 622.

FIG. 7I shows electronic device 600 at a later stage of manufacture. In the example of FIG. 7I, module 102 and module 112, as previously described, can be coupled to redistribution structure 640. Module(s) 10n (FIG. 1A) can also be coupled to redistribution structure 640. Module interconnects 234 can be coupled to terminals 646a of redistribution structure 640. Module interconnects 234 can be coupled to terminals 646a by thermocompression bonding, reflow, ultrasonic bonding, laser assisted bonding, or any other suitable bonding technique. Modules 102 and 112 (and 10n) can be in electronic communication with one another across bridge die 622 and redistribution structure 640.

FIG. 7J shows electronic device 600 at a later stage of manufacture. In the example of FIG. 7J, underfill 632 can be provided module 102 and redistribution structure 640 and between module 112 and redistribution structure 640. In some examples, underfill 632 can completely or partially fill a volume between module 102 and module 112. Underfill 632 can partially or completely cover the lateral sides of modules 102 and 112.

In accordance with various examples, underfill 632 can comprise or be referred to as capillary underfill, non-conductive paste, or non-conductive film. In some examples, underfill 632 can be urged into a gap between modules 102, 112 and redistribution structure 640 after modules 102, 112 are electrically coupled to redistribution structure 640. In some examples, underfill 632 can be pre-coated onto redistribution structure 640 prior to modules 102, 112 being coupled to redistribution structure 640. In some examples, underfill 632 can be pre-coated on modules 102, 112 prior to coupling to redistribution structure 640. In some examples, a curing process (e.g., a thermal curing process or a photocuring process) can be performed on underfill 632.

FIG. 7K shows electronic device 600 at a later stage of manufacture. In the example of FIG. 7K, lid 660 can be provided. Lid 660 can be disposed around a perimeter of electronic device 600. For example, lid can be around modules 102, 112. Lid 660 can be coupled to the inner side of redistribution structure 640. In some examples, an adhesive 662 can be used to couple lid 660 to redistribution structure 640. In some examples, external components 652 can be coupled to the outer side of base substrate 620. External components 652 can comprise passive devices in some examples.

In various examples, external interconnects 650 can be coupled to an outer side of base substrate 620. In some examples, external interconnects 650 can comprise solder balls, bumps, pads, or pillars. In some examples, electronic device 600 can comprise a land-grid array (LGA) with external interconnects 650 being omitted. In some examples, electronic device 600 can include a stiffener, similar to stiffener 502 in FIG. 5, coupled to the inner side of redistribution structure 640. In some examples, electronic device 600 can include an encapsulant, similar to encapsulant 324 in FIG. 1, disposed around modules 102 and 112. In some examples, electronic device 600 can include a BSM, similar to BSM 402 in FIG. 4, disposed over modules 102 and 112.

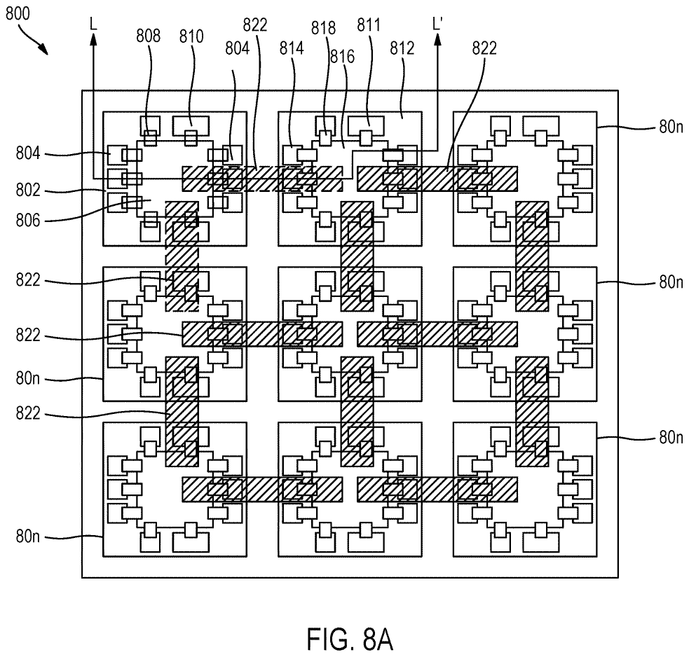

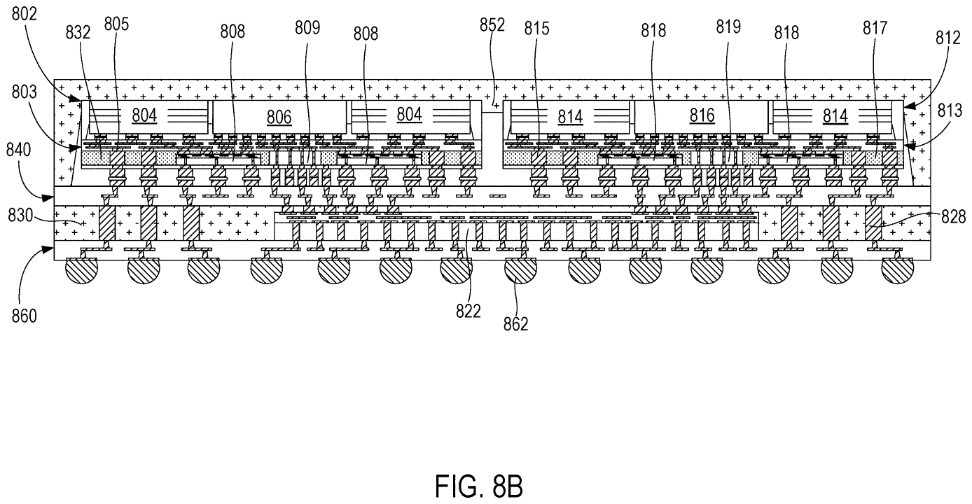

FIGS. 8A and 8B show a top view and a cross-section view, respectively, of an example electronic device 800. The cross-section of FIG. 8B is taken along the line L-L′ in FIG. 8A. In the example of FIGS. 8A and 8B, electronic device 800 comprises modules 802, 812, and 80n and bridge die 822 electrically coupled between modules 802, 812, and 80n.

Module 802 includes electronic components 804, 806, and 810 and bridge die 808. Bridge die 808 can electrically couple electronic components 804 and 806, and electronic components 810 and 806. Electronic components 804 and 810 can, in some examples, be around two, three or four sides of electronic component 806. In some examples, electronic components 804 include memory die or devices (e.g., HBM devices), electronic component 806 comprise a logic or processor die (e.g., SoC devices), and electronic component(s) 810 comprise I/O die or devices. Module 802 can include vertical interconnects 805, bridge die 808, and interconnect component 809 in an encapsulant 832. Redistribution structure 803 can be between electronic components 804, 806, 810 and vertical interconnects 805, bridge die 808, interconnect component 809, and encapsulant 832. The elements and manufacturing of module 802, 812 and 80n can be similar to or the same as those described above for module 102.

Module 812 includes electronic components 814, 816, and 811 and bridge die 818. Bridge die 818 can electrically couple electronic components 814 and 816, and electronic components 811 and 816. Electronic components 814 and 811 can, in some examples, be around two, three or four sides of electronic component 816. In some examples, electronic components 814 include memory die or devices (e.g., HBM devices), electronic component 816 comprises a logic or processor die or device (e.g., SoC device), and electronic component(s) 811 comprise I/O die or devices. Module 812 can include vertical interconnects 815, bridge die 818, and interconnect component 819 in an encapsulant 817. Redistribution structure 813 can be between electronic components 814, 816, 811 and vertical interconnects 815, bridge die 818, interconnect component 819, and encapsulant 817. Modules 80n can be similar to the same as module 802 and/or module 812. The elements and manufacturing of module 802, 812 and 80n can be similar to or the same as those described above for module 102.

Bridge die 822 can be referred to as a long bridge. As used herein, the term long bridge can refer to a bridge die that extends into the footprint of and electronically couples two or more die, and that spans the footprint of at least one intermediate die between the two coupled die. In the example of FIGS. 8A and 8B, bridge die 822 is an example of a long bridge. Bridge die 822 couples electronic component 806 of module 802 with electronic component 816 of module 812, and bridge die 822 spans the footprint of intervening memory die 804 and 814 disposed between processing die 806 and processing die 816. Bridge die 822 can thus couple electronic component 806 of module 802 with electronic component 816 of adjacent module 812 as a long bridge.

Electronic device 800 can further include redistribution structure 840, redistribution structure 860, vertical interconnects 828, and encapsulant 830. Redistribution structure 840 can be between bridge die 822 and modules 802, 812, and 80n. Redistribution structure 840 can couple modules 802, 812, 80n to bridge die 822 and vertical interconnects 828. Redistribution structure 860 can be located over a side of bridge die 822, vertical interconnects 828, and encapsulant 830 that is opposite redistribution structure 840. Encapsulant 830 and vertical interconnects 828 can extend between redistribution structure 840 and redistribution structure 860. Encapsulant 830 can surround vertical interconnects 828 and bridge die 828. External interconnects 862 can be coupled to an outer side of redistribution structure 860.

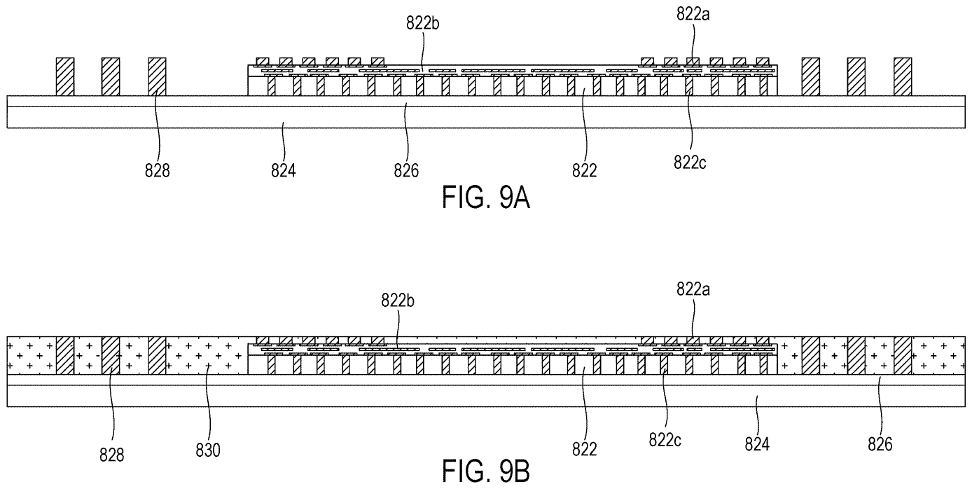

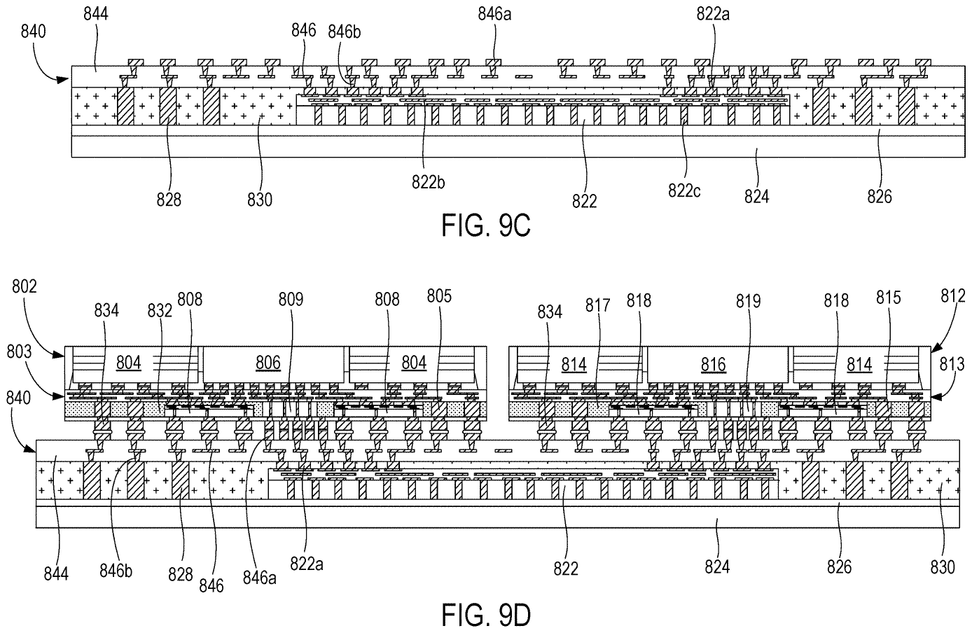

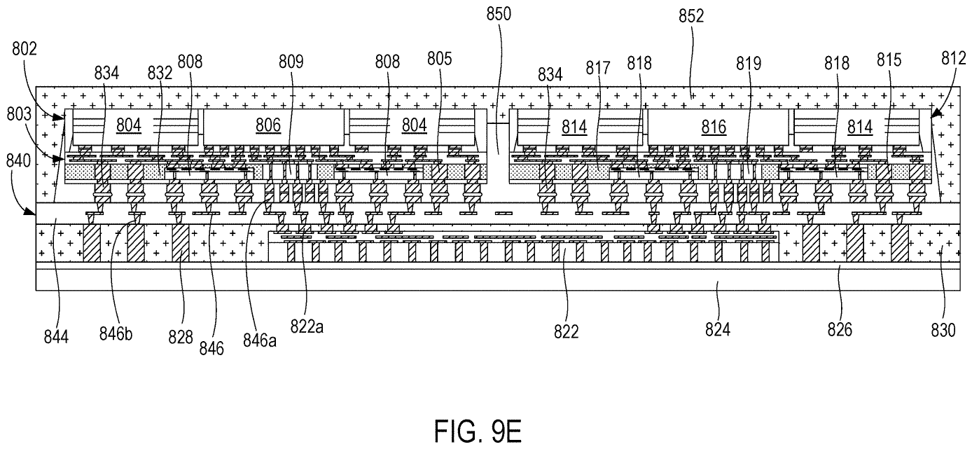

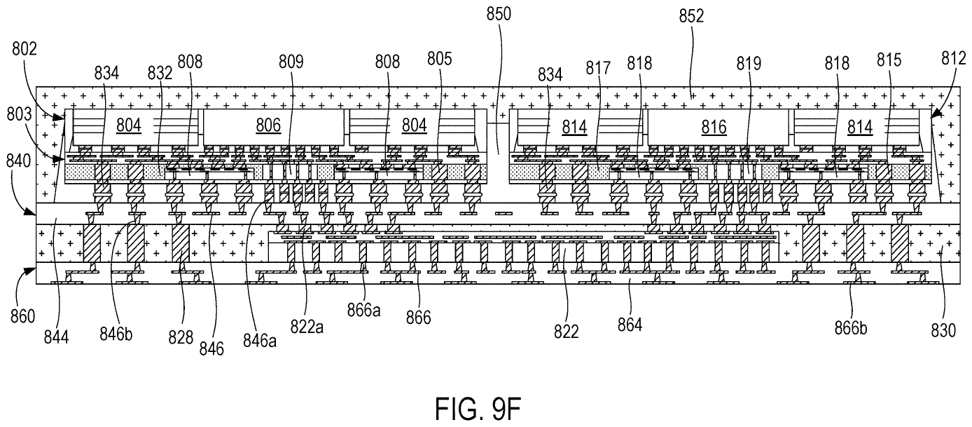

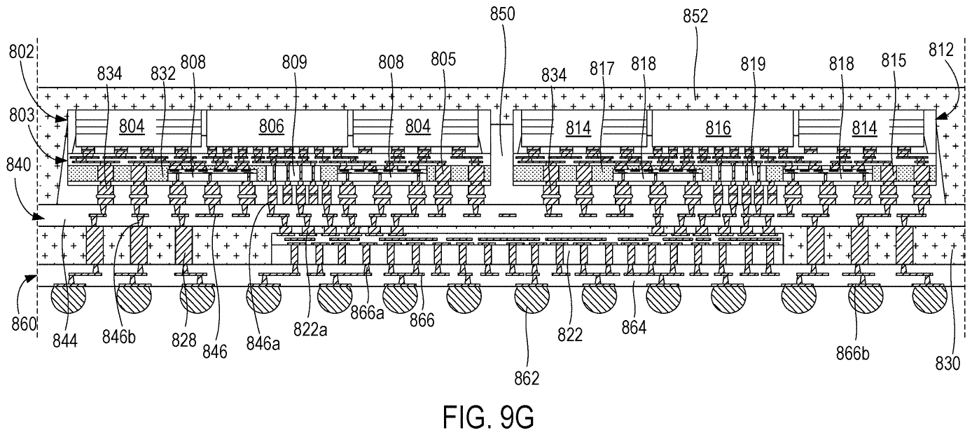

With reference now to FIGS. 9A-9G, an example method of manufacturing electronic device 800 is shown using cross sectional views taken across line L-L′ of FIG. 8A. Electronic device 800 can comprise structures or manufacturing techniques similar to those of electronic device 100 or other electronic devices described herein.

Referring to FIG. 9A, electronic device 800 is shown at an early stage of manufacture. In the example of FIG. 9A, vertical interconnects 828 can be provided over carrier 824 and temporary bond layer 826. Vertical interconnects 828 can comprise structures or manufacturing techniques similar to vertical interconnects 105 or other vertical interconnects described herein. For example, vertical interconnects 828 can comprise copper pillar that are plated over carrier 824 or pre-formed copper pins that are formed prior to coupling over carrier 824.

Bridge die 822 can be coupled to carrier 824 between vertical interconnects 828. Bridge die 822 can comprise bridge upper interconnects 822a, bridge signal distribution structure 822b, and bridge through-interconnects 822c. Bridge die 822 can comprise structures or manufacturing techniques similar to bridge die 122 or other bridge die described herein.

FIG. 9B shows electronic device 800 at a later stage of manufacture, in accordance with various examples. In the example of FIG. 9B, encapsulant 830 can be provided. Encapsulant 830 can comprise structures or manufacturing techniques similar to those of encapsulant 132 or other encapsulants described herein. Encapsulant 830 can cover lateral sides of vertical interconnects 828 and bridge die 822. An upper side of vertical interconnects 828 and bridge upper interconnects 822a can be exposed from and/or coplanar with encapsulant 830. In some examples, encapsulant 830 can be between and/or contact bridge upper interconnects 822a. In some examples, bridge die 822 can include a bridge passivation, similar to bridge passivation 225 in FIG. 2D, which can prevent or block encapsulant 830 from flowing between bridge upper interconnects 822a.

FIG. 9C shows electronic device 800 at a later stage of manufacture. In the example of FIG. 9C, redistribution structure 840 can be provided. Redistribution structure 840 can be provided over the coplanar sides of encapsulant 830, vertical interconnects 828, and bridge upper interconnects 822a of bridge die 822.

In accordance with various examples, redistribution structure 840 includes dielectric structure 844 and conductive structure 846. Elements or layers of conductive structure 846 can be interleaved with elements or layers of dielectric structure 844. In some examples, redistribution structure 840 can be an RDL substrate, as previously described. In some examples, redistribution structure 840 can comprise a pre-formed substrate, as previously described.

In accordance with various examples, conductive structure 846 includes inner terminals 846a located along an inner side of redistribution structure 840. Inner terminals 846a can comprise or be referred to as pads, lands, UBMs (Under Bump Metals), studs, bumps, or pillars. Conductive structure 846 further includes outer terminals 846b located at an outer side of redistribution structure 840. Outer terminals 846b can comprise or be referred to as vias, pads, lands, UBMs (Under Bump Metals), studs, bumps, or pillars. Outer terminals 846b can be coupled to and/or can contact vertical interconnects 828 and interconnects 822a of bridge die 822. Redistribution structure 840 can comprise structures or manufacturing techniques similar to those of redistribution structure 103 or other redistribution structures described herein.

FIG. 9D shows electronic device 800 at a later stage of manufacture. In the example of FIG. 9D, modules 802 and 812 (and 80n FIG. 8A) can be coupled to redistribution structure 840. Module interconnects 834 of modules 802 and 812 can be coupled to inner terminals 846a of redistribution structure 840.

In various examples, modules 802 and 812 can comprise structures and manufacturing techniques similar to those of modules 102 and 112, as previously described. As shown in the example of FIG. 8A, modules 802 and 812 can comprise a central processing die 806, 816 with input/output (i/o) die 810, 811 and memory die 804, 814 disposed around a perimeter of the processing die. Die within an individual module 802, 812 can communicate across bridge die 808 embedded in the individual module 802, 812. The processing die 806 in module 802 can communicate across bridge die 822 with processing die 816 in module 812. In some examples, interconnect components 809, 819 of modules 802, 812 can be coupled between processing die 806, 816 and module interconnects 834. Interconnect components 809, 819 can provide high density routing to and from electronic components 806, 816.

In accordance with various embodiments, underfill 833 can be provided between modules 802, 812 and redistribution structure 840. The elements, materials, and/or manufacturing techniques of underfill 833 can be similar to or the same as those of underfill 632, as previously described.

FIG. 9E shows electronic device 800 at a later stage of manufacture. In the example of FIG. 9E, underfill 850 and encapsulant 852 can be provided. Underfill 850 can be provided between modules 802, 812 and redistribution structure 840. The elements, materials, and/or manufacturing techniques of underfill 833 can be similar to or the same as those of underfill 632 or other underfills described herein.

Encapsulant 852 can be provided over modules 802 and 812 and redistribution structure 840. The elements, materials, and/or manufacturing techniques of encapsulant 852 can be similar to or the same as those of encapsulant 132 or other encapsulants described herein.

FIG. 9F shows a cross-sectional view of electronic device 800 at a later stage of manufacture. In the example shown in FIG. 9F, carrier 824 can be removed from the bottom sides (as depicted) of bridge die 822, vertical interconnects 828, and encapsulant 830. Carrier 824 and temporary bond layer 826 can comprise structures and manufacturing techniques similar to those of carrier 202 and temporary bond layer 204, respectively, or of other carriers and temporary bond layers described herein.

In various examples, redistribution structure 860 can be provided over bridge die 822, vertical interconnects 828, and encapsulant 830 opposite redistribution structure 840. Redistribution structure 860 can be provided on the coplanar sides of encapsulant 830, vertical interconnects 828, and bridge die 822.

In accordance with various examples, redistribution structure 860 includes dielectric structure 864 and conductive structure 866. Elements or layers of conductive structure 866 can be interleaved with elements or layers of dielectric structure 864. In some examples, redistribution structure 860 can be an RDL substrate, as previously described. In some examples, redistribution structure 860 can comprise a pre-formed substrate, as previously described.

In accordance with various examples, conductive structure 866 includes inner terminals 866a located along an inner side of redistribution structure 860. Inner terminals 866a can comprise or be referred to as vias, pads, lands, UBMs (Under Bump Metals), studs, bumps, or pillars. Conductive structure 866 further includes outer terminals 866b located at an outer side of redistribution structure 860. Outer terminals 866b can comprise or be referred to as vias, pads, lands, UBMs (Under Bump Metals), studs, bumps, or pillars. Inner terminals 866a can be coupled to and/or can contact vertical interconnects 828 and interconnects 822c of bridge die 822. Redistribution structure 860 can comprise structures or manufacturing techniques similar to those of redistribution structure 103 or other redistribution structures described herein.

FIG. 9G shows electronic device 800 at a later stage of manufacture. In the example of FIG. 9G, external interconnects 862 can be coupled to outer terminals 866b of redistribution structure 860. In some examples, external interconnects 862 can comprise solder balls, bumps, pads, or pillars. In some examples, electronic device 800 can comprise a land-grid array (LGA) with external interconnects 862 being omitted.

In various examples, singulation can also be performed. In some examples, singulation can be performed by cutting through saw streets S disposed around a perimeter of electronic devices 800, thereby separating individual electronic devices 800 from one another. Singulation can comprise structures and manufacturing techniques as previously described.

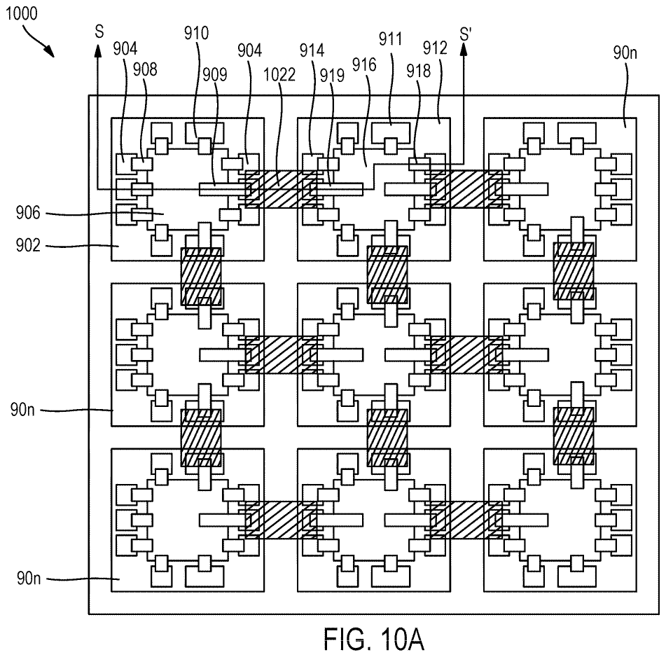

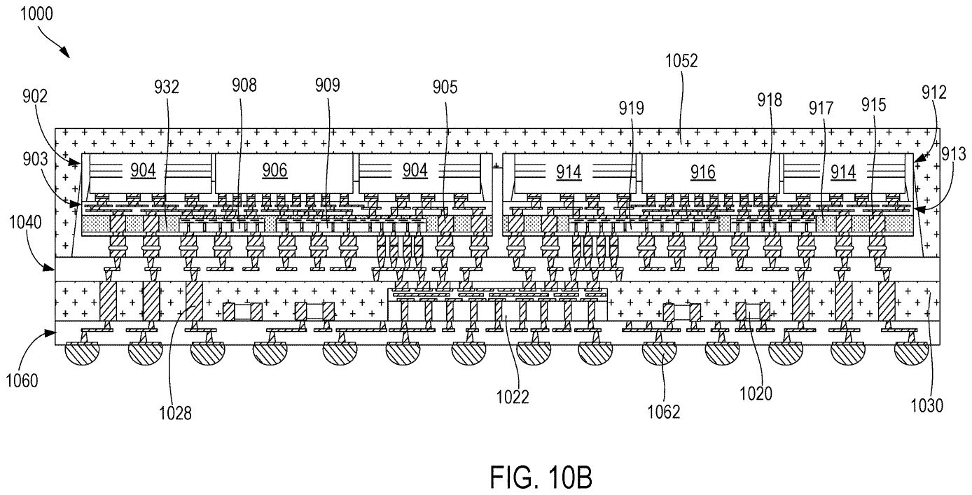

FIGS. 10A and 10B show a top view and a cross-section view, respectively, of an example electronic device 1000. In the example of FIGS. 10A and 10B, electronic device 1000 comprises modules 902, 912, 90n and bridge die 1022. The cross-section of FIG. 10B is taken along the line S-S′ in FIG. 10A. In the example of FIGS. 10A and 10B, bridge die 1022 are electrically coupled between modules 902, 912, and 90n.

Module 902 includes electronic components 904, 906, and 910, bridge die 908, and interconnect component 909. Bridge die 908 can electrically couple electronic components 904 and 906, and electronic components 910 and 906. Electronic components 904 and 910 can, in some examples, be around two, three or four sides of electronic component 906. In some examples, electronic components 904 include memory die or devices (e.g., HBM devices), electronic component 906 comprise a logic or processor die (e.g., SoC devices), and electronic component(s) 910 comprise I/O die or devices. Module 902 can include vertical interconnects 905, bridge die 908, and interconnect components 909 in an encapsulant 932. Redistribution structure 903 can be between electronic components 904, 906, 910 and vertical interconnects 905, bridge die 908, interconnect components 909, and encapsulant 932.

Module 912 includes electronic components 914, 916, and 911, bridge die 918, and interconnect components 919. Bridge die 918 can electrically couple electronic components 914 and 916, and electronic components 911 and 916. Electronic components 914 and 911 can, in some examples, be around two, three or four sides of electronic component 916. In some examples, electronic components 914 include memory die or devices (e.g., HBM devices), electronic component 916 comprises a logic or processor die or device (e.g., SoC device), and electronic component(s) 911 comprise I/O die or devices. Module 912 can include vertical interconnects 915, bridge die 918, and interconnect components 919 in an encapsulant 917. Redistribution structure 913 can be between electronic components 914, 916, 911 and vertical interconnects 915, bridge die 918, interconnect components 919, and encapsulant 917. Modules 90(n) can be similar to or the same as module 902 and/or module 912. The elements and manufacturing of module 902, 912 and 90n can be similar to or the same as those described above for module 102.

In some examples, interconnect components 909 can be coupled between electronic component 906 and one or more of electronic components 904 and/or 910 and between electronic component 906 and bridge die 1022. For example, interconnect component 909 can electrically couple electronic component 906 to electronic component(s) 904 and/or 910 within module 902 and to bridge die 1022. In some examples, interconnect components 919 can be coupled between electronic component 916 and one or more of electronic components 914 and/or 911 and between electronic component 916 and bridge die 1022. For example, interconnect component 919 can electrically couple electronic component 916 to electronic component(s) 914 and/or 911 within module 912 and to bridge die 1022. In this regard, electronic component 906 of module 902 and electronic component 916 of module 912 can be in electrical communication via interconnect component 909, bridge die 1022, and interconnect component 919. In some examples, interconnect components 909 and 919 can include a signal distribution structure and upper interconnects similar to signal distribution structure 223 and bridge upper interconnects 224, respectively, of bridge die 108 in FIG. 2B. In some examples, the upper interconnects of interconnect component 909 and/or interconnect component 919 can be surround by a passivation structure, similar to bridge passivation 225 in FIG. 2B.

Bridge die 1022 can be referred to as a short bridge. As used herein, the term short bridge can refer to a bridge die that does not extend into the footprint of the electronic component to which it is coupled. In the example of FIGS. 10A and 10B, bridge die 1022 is an example of a short bridge. Bridge die 1022 couples electronic component 906 of module 902 with electronic component 916 of module 912, and the footprint of bridge die 1022 does not vertically overlap the footprint of either electronic component 906 or electronic component 916. Rather the footprint of bridge die 1022 starts and/or ends outside the footprints of electronic component 906 and electronic component 919. Bridge die 1022 can thus couple electronic component 906 of module 902 with electronic component 916 of adjacent module 912 as a short bridge.

Electronic device 1000 can further include redistribution structure 1040, redistribution structure 1060, vertical interconnects 1028, and encapsulant 1030. Redistribution structure 1040 can be between bridge die 1022 and modules 902, 912, and 90n. Redistribution structure 1040 can couple modules 902, 912, 90n to bridge die 1022 and vertical interconnects 1028. Redistribution structure 1060 can be located over a side of bridge die 1022, vertical interconnects 1028, and encapsulant 1030 that is opposite redistribution structure 1040. Encapsulant 1030 and vertical interconnects 1028 can extend between redistribution structure 1040 and redistribution structure 1060. Encapsulant 1030 can surround vertical interconnects 1028 and bridge die 1028. In some examples, electronic device 1000 can include one or more electronic components 1020 in encapsulant 1030. Encapsulant 1052 can be over modules 902, 912 and 90n. External interconnects 1062 can be coupled to an outer side of redistribution structure 1060.

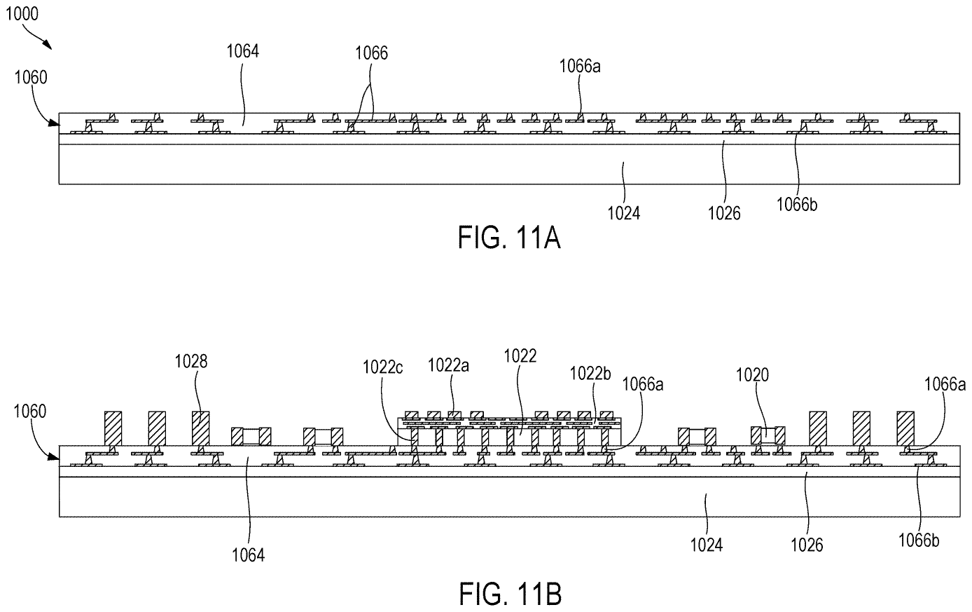

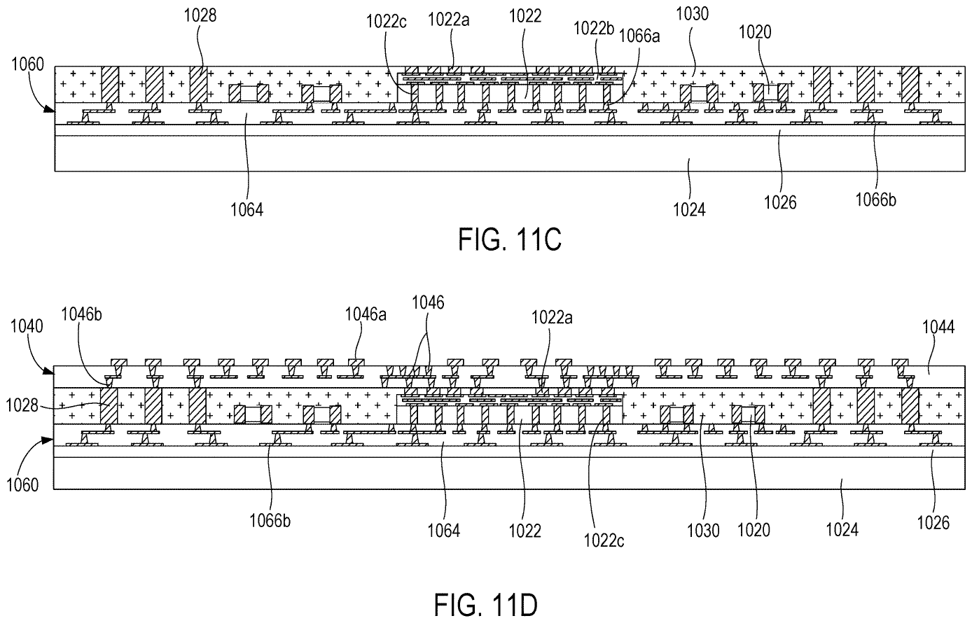

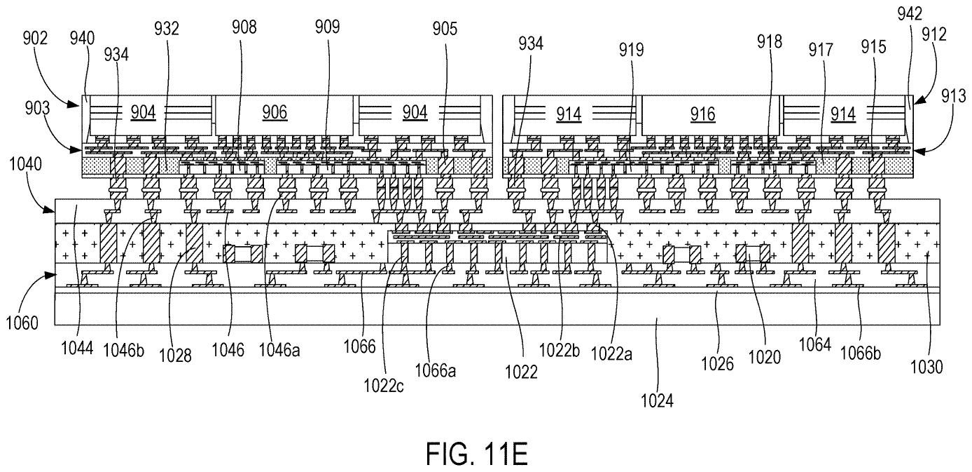

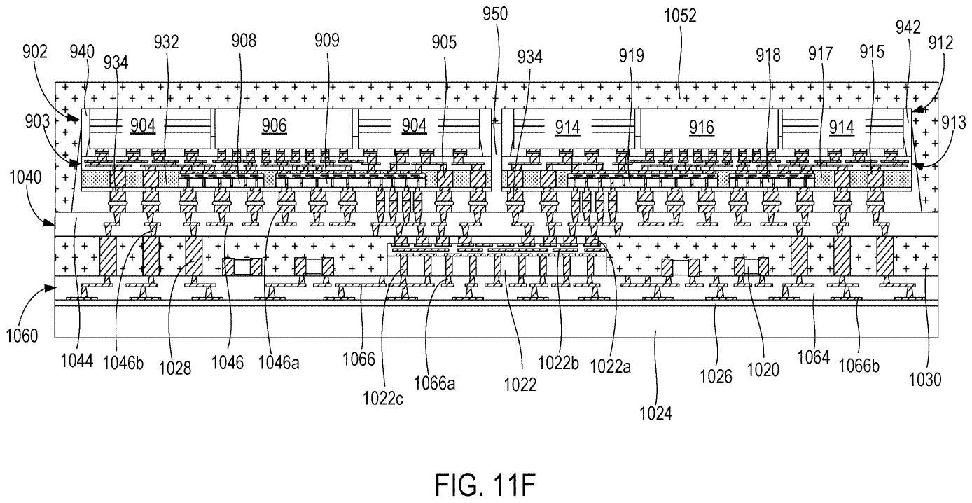

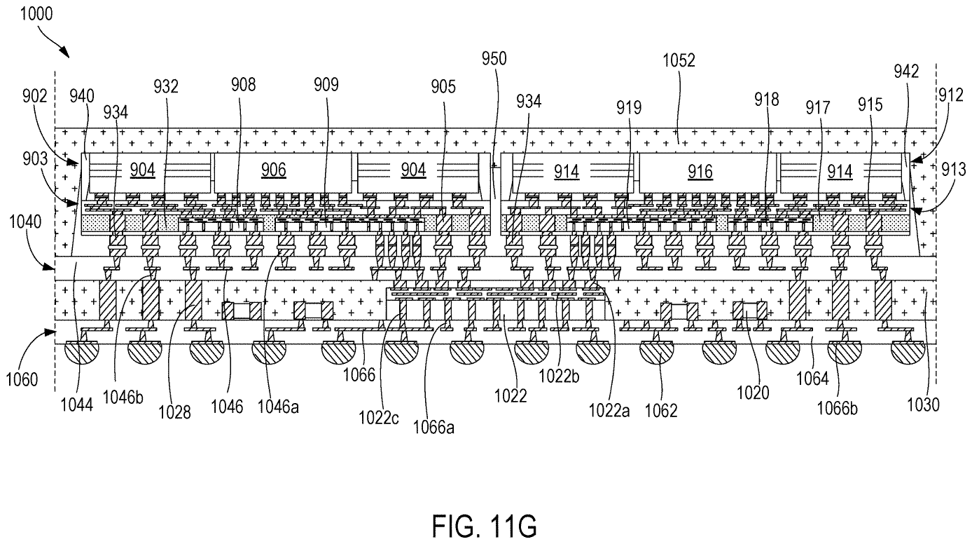

With reference now to FIGS. 11A-11G, an example method of manufacturing electronic device 1000 is shown using cross sectional views taken across line S-S′ of FIG. 10A. Electronic device 1000 can comprise structures and manufacturing techniques similar to electronic device 800 of FIGS. 8A and 8B.

Referring to FIG. 11A, electronic device 1000 is shown at an early stage of manufacture. In the example of FIG. 11A, redistribution structure 1060 is provided. Redistribution structure 1060 can be provided over temporary bond layer 1026 and carrier 1024. Redistribution structure 1060 can comprise structures and manufacturing techniques similar to redistribution structure 860 or other redistribution layers described herein. Carrier 1024 and temporary bond layer 1026 can comprise structures and manufacturing techniques similar to those of carrier 824 and temporary bond layer 826 or other carriers and temporary bond layers described herein.

In accordance with various examples, redistribution structure 1060 includes dielectric structure 1064 and conductive structure 1066. Elements or layers of conductive structure 1066 can be interleaved with elements or layers of dielectric structure 1064. In some examples, redistribution structure 1060 can be an RDL substrate, as previously described. In some examples, redistribution structure 1060 can comprise a pre-formed substrate, as previously described.

In accordance with various examples, conductive structure 1066 includes inner terminals 1066a located along an inner side of redistribution structure 1060. Inner terminals 1066a can comprise or be referred to as pads, lands, UBMs (Under Bump Metals), studs, bumps, or pillars. Conductive structure 1066 further includes outer terminals 1066b located at an outer side of redistribution structure 1060. Outer terminals 1066b can comprise or be referred to as vias, pads, lands, UBMs (Under Bump Metals), studs, bumps, or pillars.

FIG. 11B shows electronic device 1000 at a later stage of manufacture, in accordance with various examples. In the example of FIG. 11B, vertical interconnects 1028 and bridge die 1022 can be provided over redistribution structure 1060. Vertical interconnects 1028 can be coupled to and/or in contact with inner terminals 1066a of redistribution structure 1060. Vertical interconnects 1028 can comprise structures and manufacturing techniques similar to vertical interconnects 828 or other vertical interconnects described herein.

Bridge die 1022 can be provided between vertical interconnects 1028. Bridge die 1022 can comprise bridge upper interconnects 1022a, bridge signal distribution structure 1022b, and bridge through-interconnects 1022c. Bridge through-interconnects 1022c can be coupled to inner terminals 1066a of redistribution structure 1060. Bridge die 1022 can comprise structures or manufacturing techniques similar to bridge die 122 or other bridge die described herein.

In some examples, one or more electronic components 1020 can be provided over redistribution structure 1060. In some examples, electronic components 1020 can comprise passive devices (e.g., capacitors, resistors, inductors, IPD, etc.). Electronic components 1020 can be coupled to inner terminals 1066a of redistribution structure 1060. In some examples, short bridge die 1022 can allow for a greater number of electronic components 1020 within electronic device 1000, as compared to device including a long bridge die.

FIG. 11C shows electronic device 1000 at a later stage of manufacture, in accordance with various examples. In the example of FIG. 11C, encapsulant 1030 can be provided. Encapsulant 1030 can comprise structures and manufacturing techniques similar to encapsulant 830 or other encapsulants described herein. Encapsulant 1030 can be coupled to the lateral sides of vertical interconnects 1028, an inner side of redistribution structure 1060, and lateral sides of bridge die 1022. In some examples, encapsulant 1030 can be disposed over bridge die 1022 with bridge upper interconnects 1022a and vertical interconnects 1028 exposed from encapsulant 1030.

FIG. 11D shows electronic device 1000 at a later stage of manufacture, in accordance with various examples. In the example of FIG. 11D, redistribution structure 1040 can be provided. Redistribution structure 1040 can be provided over the coplanar sides of encapsulant 1030, vertical interconnects 1028, and bridge upper interconnects 1022a of bridge die 1022.

In accordance with various examples, redistribution structure 1040 includes dielectric structure 1044 and conductive structure 1046. Elements or layers of conductive structure 1046 can be interleaved with elements or layers of dielectric structure 1044. In some examples, redistribution structure 1040 can be an RDL substrate, as previously described. In some examples, redistribution structure 1040 can comprise a pre-formed substrate, as previously described.

In accordance with various examples, conductive structure 1046 includes inner terminals 1046a located along an inner side of redistribution structure 1040. Inner terminals 846a can comprise or be referred to as pads, lands, UBMs (Under Bump Metals), studs, bumps, or pillars. Conductive structure 1046 further includes outer terminals 1046b located at an outer side of redistribution structure 1040. Outer terminals 1046b can comprise or be referred to as vias, pads, lands, UBMs (Under Bump Metals), studs, bumps, or pillars. Outer terminals 1046b can be coupled to and/or can contact vertical interconnects 1028 and interconnects 1022a of bridge die 1022. Redistribution structure 1040 can comprise structures or manufacturing techniques similar to those of redistribution structure 103 or other redistribution structures described herein.

FIG. 11E shows electronic device 1000 at a later stage of manufacture, in accordance with various examples. In the example of FIG. 11E, modules 902 and 912 (and 90n (FIG. 10A) can be provided. Modules 902 and 912 (and 90n) can be coupled to redistribution structure 1040. For example, module interconnects 934 can be coupled to terminals 1066a of redistribution structure 1060. Conductive structure 1066 can electrically couple bridge die 1022 to interconnect components 909 and 919, which are coupled to electronic components 906 and 916, respectively.

FIG. 11F shows electronic device 1000 at a later stage of manufacture. In the example of FIG. 11F, underfill 950 and encapsulant 1052 can be provided. Underfill 950 comprises structures and manufacturing techniques similar to underfill 850 or other underfills described herein. Encapsulant 1052 can comprise structures or manufacturing techniques similar to encapsulant 852 or other encapsulants described herein.

In various examples, underfill 950 can be disposed between modules 902 and 912. Underfill 950 can be disposed between module 902 or 912 and redistribution structure 1040. Underfill 950 can be disposed around the lateral sides of modules 902 and 912. Encapsulant 1052 can be disposed over and around modules 902 and 912. Encapsulant 1052 can extend into a gap between modules 902 and 912 and over underfill 950. In some examples, encapsulant 1052 can contact the back side of electronic component(s) 906, 904, 916 and/or 914. In other examples, module encapsulants 940, 942 can be over the backside of electronic component(s) 906, 904, 916 and/or 914, such that module encapsulants 940, 942 is between encapsulant 1052 and electronic component(s) 906, 904, 916 and 914. In some examples, encapsulant 1052 can be coplanar with module encapsulants 940, 942 and the backsides of electronic component(s) 906, 904, 916 and/or 914.

FIG. 11G shows a cross-sectional view of electronic device 1000 at a later stage of manufacture. In the example of FIG. 11G, carrier 1024 can be removed from the outer side of redistribution structure 1060. External interconnects 1062 can be coupled to outer terminals 1066b of redistribution structure 1060. In some examples, external interconnects 1062 can comprise solder balls, bumps, pads, or pillars. In some examples, electronic device 1000 can comprise a land-grid array (LGA) with external interconnects 1062 being omitted.

In various examples, singulation can also be performed. In some examples, singulation can be performed by cutting through saw streets disposed around a perimeter of electronic devices 1000, thereby separating individual electronic devices 1000 from one another. Singulation can include cutting or sawing through encapsulant 1052, redistribution structure 1040, encapsulant 1030, and redistribution structure 1060. After singulation, encapsulant 1052, redistribution structure 1040, encapsulant 1030, and redistribution structure 1060 can be coplanar with one another.

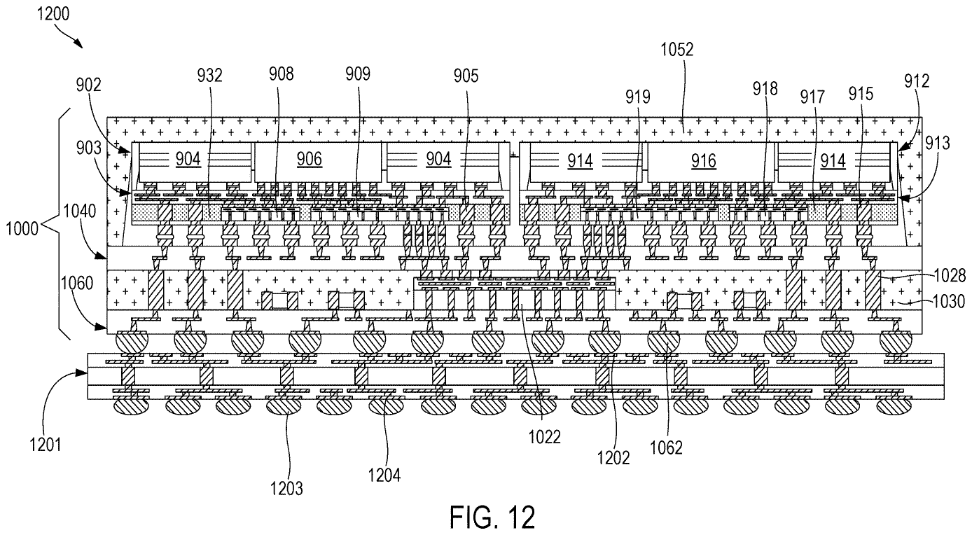

Referring now to FIG. 12, electronic device 1200 is shown, in accordance with various examples. In the example of FIG. 12, electronic device 1000 is coupled to base substrate 1201. External interconnects 1062 of electronic device 1000 of can be coupled to inner terminals 1202 of base substrate 1201.

Base substrate 1201 can comprise structures and manufacturing techniques similar to base substrate 120 of electronic device 100 or other substrates or redistribution structures described herein. In some examples, base substrate 1201 can comprise or be referred to as a pre-formed or laminate substrate, as previously described.

In some examples, electronic device 1200 can include external interconnects 1203. External interconnects 1203 can be coupled to outer terminals 1204 of base substrate 1201. The conductive structure of base substrate 1201 can couple inner terminals 1202 and outer terminals 1204. External interconnects 1203 can serve as external input/output terminals of electronic device 1200 and/or can be configured to couple electronic device 1200 to a next level device (e.g., PCB, motherboard, etc.).

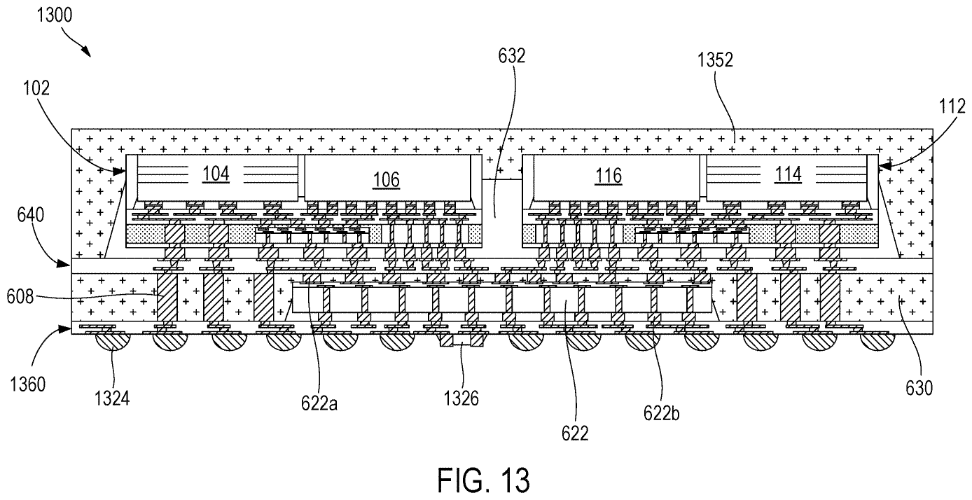

Referring now to FIG. 13, an example electronic device 1300 is shown. Electronic device 1300 can be similar to electronic device 600 of FIGS. 6A and 6B, but with base substrate 620 of electronic device 600 replaced with redistribution structure 1360 and encapsulant 1352 disposed over modules 102 and 112 (and over module(s) 10n, see FIG. 6A). In this regard, elements with like numbering to electronic device 600 denote the same elements in electronic device 1300 and may not be repeated for the sake of brevity.

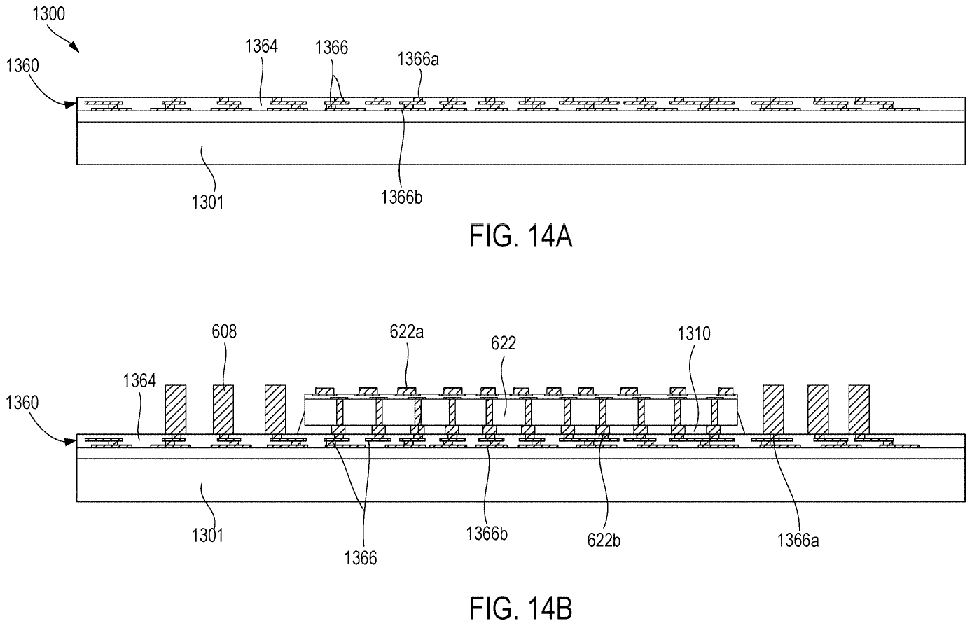

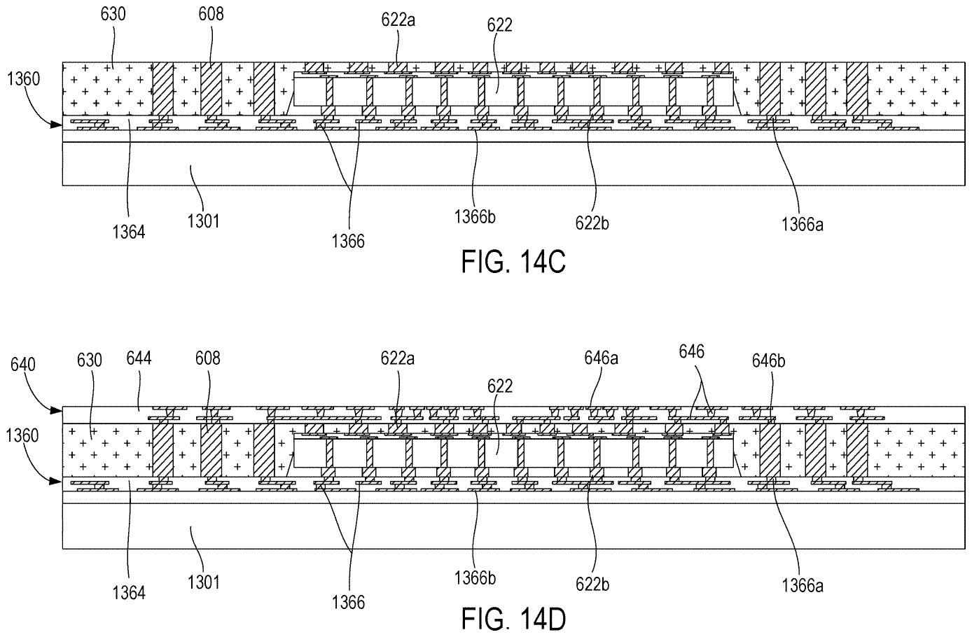

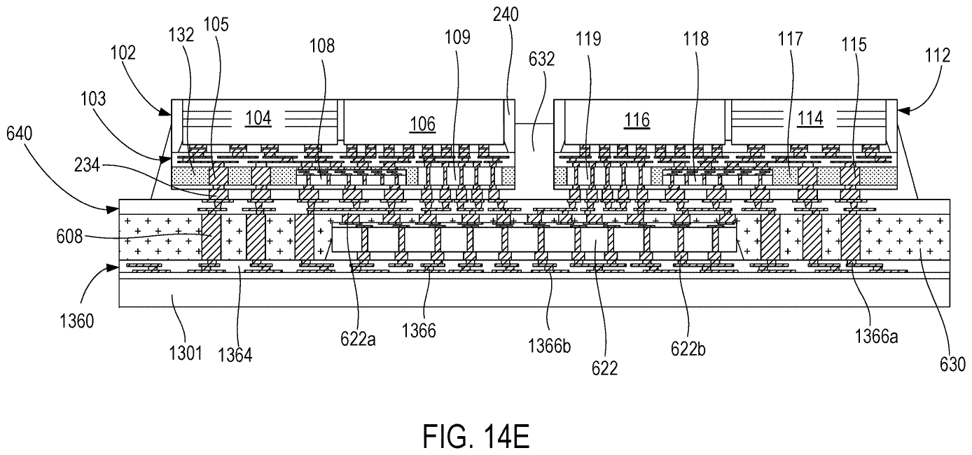

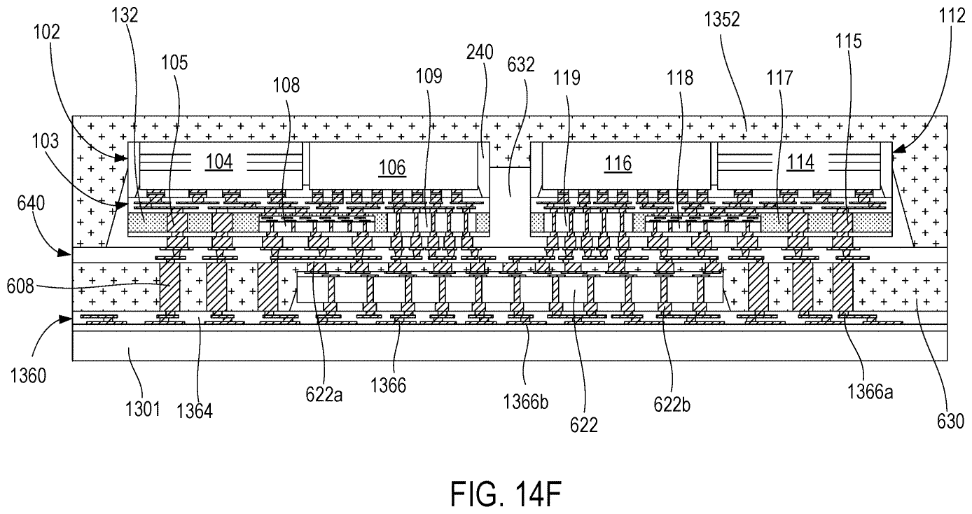

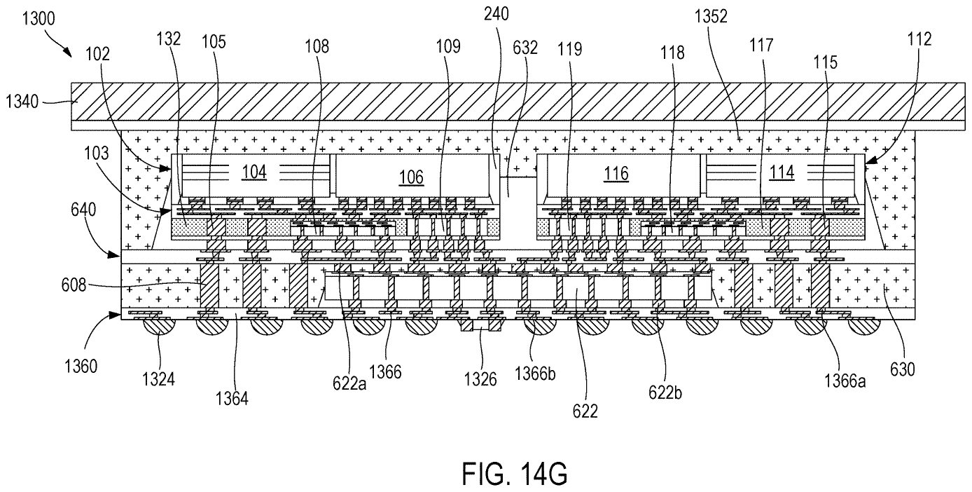

FIGS. 14A-14G show a method for manufacturing electronic device 1300, in accordance with various embodiments. Various components and manufacturing techniques of electronic device 1300 can be similar to or the same as those described for electronic device 600, electronic device 800, or other electronic devices described herein.

In the example of FIG. 14A, redistribution structure 1360 can be provided over carrier 1301. Carrier 1301 can comprise structures and manufacturing techniques similar to carrier 202 or other carriers described herein. In some examples, a temporary bond layer, similar to temporary bond layer 204, can be provided on the upper side of carrier 1301 to facilitate the separation of redistribution structure 1360 from carrier 1301.

In accordance with various examples, redistribution structure 1360 includes dielectric structure 1364 and conductive structure 1366. Elements or layers of conductive structure 1366 can be interleaved with elements or layers of dielectric structure 1364. Redistribution structure 1360 can comprise structures and manufacturing techniques similar to redistribution structure 1060 or other redistribution structures described herein. In some examples, redistribution structure 1360 can be an RDL substrate, as previously described.

In accordance with various examples, conductive structure 1366 includes inner terminals 1366a located along an inner side of redistribution structure 1360. Inner terminals 1366a can comprise or be referred to as pads, vias, lands, UBMs (Under Bump Metals), studs, bumps, or pillars. Conductive structure 1366 further includes outer terminals 1366b located at an outer side of redistribution structure 1360. Outer terminals 1366b can comprise or be referred to as pads, lands, UBMs (Under Bump Metals), studs, bumps, or pillars.

FIG. 14B shows electronic device 1300 at a later stage of manufacture. In the example of FIG. 14B, vertical interconnects 608, as previously described, can be provided. Vertical interconnects 608 can be formed over redistribution structure 1360. For example, vertical interconnects 608 can be coupled to inner terminal 1366a of redistribution structure 1360. Vertical interconnects 608 can be plated pillars formed on inner terminal 1366a or pre-formed pins coupled to inner terminal 1366a.

Bridge die 622, as previously described, can be coupled to redistribution structure 1360 in various examples. Bridge interconnects 622b can be coupled to inner terminal 1366a of redistribution structure 1360. Bridge upper interconnects 622a can be oriented away from redistribution structure 1360. Vertical interconnects 608 can be arranged around the lateral sides of bridge die 622. In some examples, an underfill 1310 can be between bridge die 622 and the inner side redistribution structure 1360.

FIG. 14C shows electronic device 1300 at a later stage of manufacture. In the example of FIG. 14C, encapsulant 630, as previously described, can be provided. The upper sides of vertical interconnects 608 and interconnects 622a are exposed from encapsulant 630. In some examples, the upper sides of encapsulant 630, vertical interconnects 608, and interconnects 622a can be substantially coplanar.

FIG. 14D shows electronic device 1300 at a later stage of manufacture. In the example of FIG. 14D, redistribution structure 640, as previously described, can be provided over encapsulant 630, vertical interconnects 608, and interconnects 622a. Redistribution structure 640 can include dielectric structure 644 and conductive structure 646 Outer terminals 646b of conductive structure 646 are coupled to vertical interconnects 608 and interconnects 622a.

FIG. 14E shows electronic device 1300 at a later stage of manufacture. In the example of FIG. 14E, modules 102 and 112 (and 10n see FIG. 1A), as previously described, can be disposed over redistribution structure 640. Module interconnects 234 can be coupled to inner terminals 646a of redistribution structure 640. Underfill 632 can be provided between modules 102 and 112 and the inner side of redistribution structure 640, as previously described.

FIG. 14F shows electronic device 1300 at a later stage of manufacture. In the example of FIG. 14F, encapsulant 1352 can be provided over module 102 and module 112 (and module(s) 10n FIG. 1A). Encapsulant 1352 can be disposed around the lateral sides of modules 102 and 112, and between modules 102 and 112. Structures and manufacturing techniques of encapsulant 1352 can be similar to those of other mold materials or encapsulants described herein. In some examples, back grinding can be performed to expose the outer sides of modules 102 and 112 from encapsulant 1352. The exposed sides of modules 102 and 112 can be coupled to a lid or BSM in some examples. Various examples can similarly include a heat spreader, stiffener, lid, or other additional structures coupled to the outer side of modules 102, 112 or encapsulant 1352.

FIG. 14G shows electronic device 1300 at a later stage of manufacture. In the example of FIG. 14G, carrier 1301 can be released and carrier 1340 can be provided over the outer side of encapsulant 1352 over modules 102, 112. Carrier 1340 can comprise structures and manufacturing techniques similar to carrier 1301 or other carriers described herein. External interconnects 1324 can be coupled to outer terminal 1366b of redistribution structure 1360. Structures or manufacturing techniques of external interconnects 1324 can be similar to those of external interconnects 124 or other external interconnects described herein. Electronic components 1326 can also be coupled to outer terminal 1366b at an outer side of redistribution structure 1360. In some examples, electronic components 1326 can comprise passive devices. In some examples, a singulation can be performed to separate individual electronic devices 1300 from one another. Singulation can include cutting or sawing through encapsulant 1352, redistribution structure 640, encapsulant 630, and redistribution structure 1360. In some examples, after singulation encapsulant 1352, redistribution structure 640, encapsulant 630, and redistribution structure 1360 can be substantially coplanar with one another.

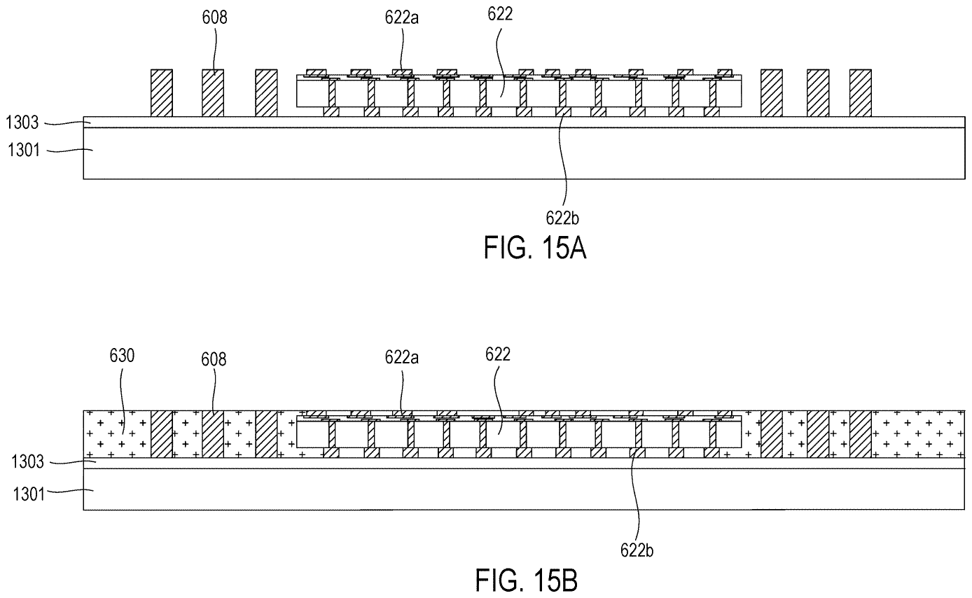

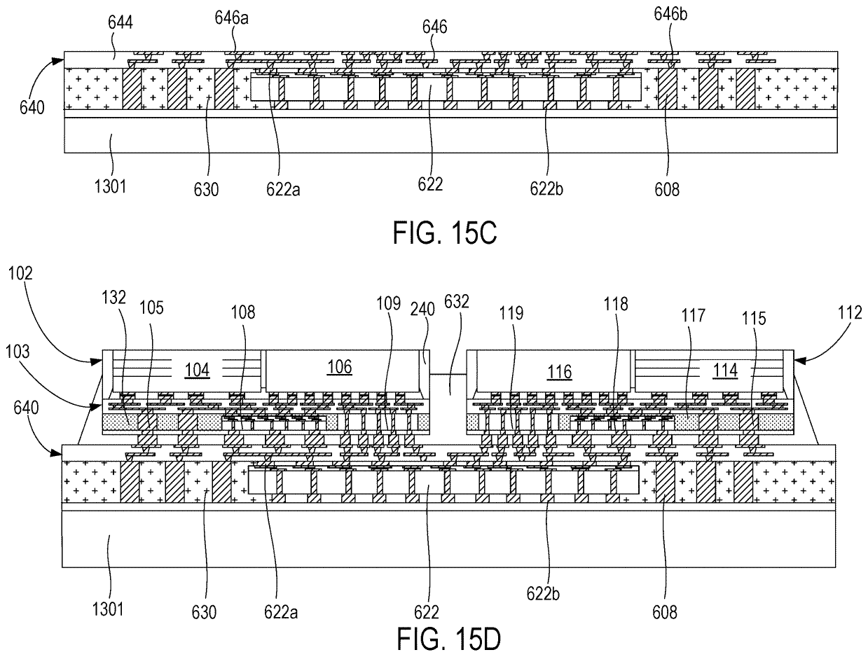

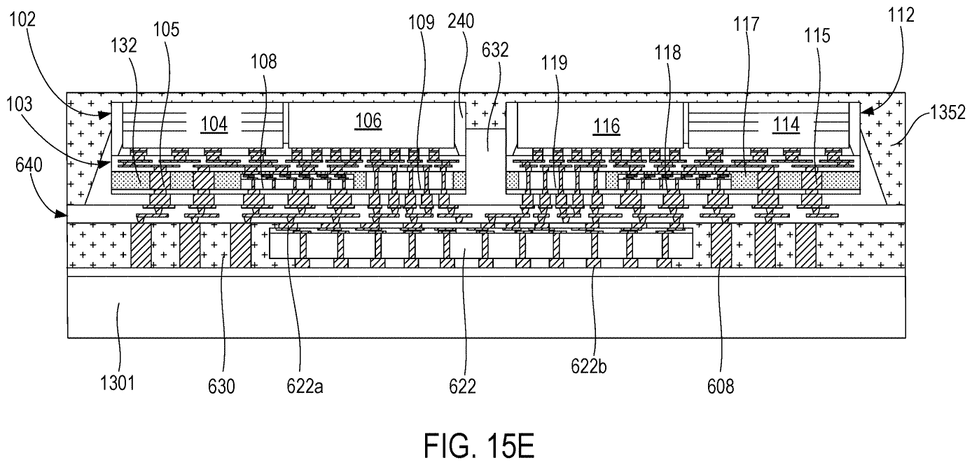

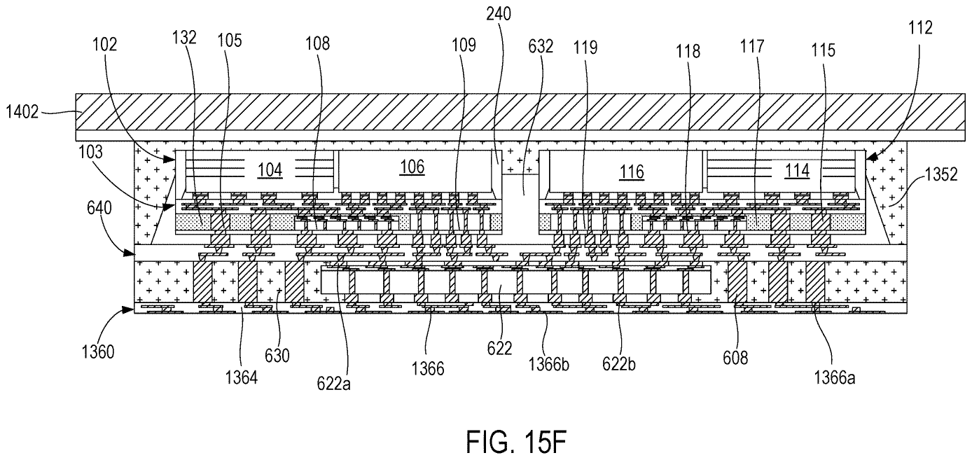

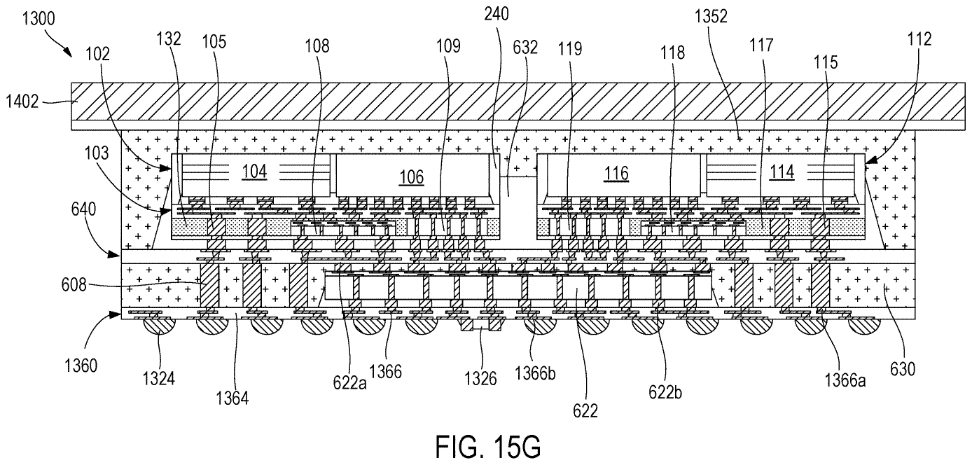

With reference now to FIGS. 15A-15G, another method for making electronic device 1300 is shown, in accordance with various examples. The structures and manufacturing techniques used in the example method of FIGS. 15A-15G can be similar to those shown in FIGS. 11A-11G or of other methods described herein.

FIG. 15A shows electronic device 1300 at an early stage of manufacture. The example method of FIGS. 15A-15G can comprise structures and manufacturing techniques similar to those of the example method shown in FIGS. 14A-14G, and the example method of FIGS. 15A-15G can include providing redistribution structure 1360 at a later stage of manufacture than the example method shown in FIGS. 14A-14G.

In the example of FIG. 15A, vertical interconnects 608 and bridge die 622 can be provided over carrier 1301. Carrier 1301 can comprise a temporary bond layer 1303. Carrier 1301 and temporary bond layer 1303 can comprise structures and manufacturing techniques similar to other carriers and temporary bond layers described herein. Bridge interconnects 622b can be oriented towards carrier 1301, and bridge upper-interconnects 622a can be oriented away from carrier 1301.

FIG. 15B shows electronic device 1300 at a later stage of manufacture. In the example of FIG. 15B, encapsulant 630 can be provided, as previously described. In some examples, a portion of encapsulant 630 can be removed (e.g., via back grinding) to expose the upper sides of vertical interconnects 608 and the upper sides of bridge interconnects 622a.

FIG. 15C shows electronic device 1300 at a later stage of manufacture. In the example of FIG. 15C, redistribution structure 640, including dielectric structure 644 and conductive structure 646, can be provided, as previously described. Outer terminals 646b of conductive structure 646 can be coupled to the upper sides of vertical interconnects 608 and the upper sides of bridge interconnects 622a.

FIG. 15D shows electronic device 1300 at a later stage of manufacture. In the example of FIG. 15D, modules 102 and 112 (and module(s) 10(n) FIG. 1A) can be coupled to redistribution structure 640. Underfill 632 can be provided between module 102 and module 112 (and module(s) 10(n)) and redistribution structure 640, as previously described.

FIG. 15E shows electronic device 1300 at a later stage of manufacture. In the example of FIG. 15E, encapsulant 1352 can be provided over modules 102, 112 and underfill 632, as previously described.

FIG. 15F shows electronic device 1300 at a later stage of manufacture. In the example of FIG. 15F, carrier 1301 can be released and carrier 1402 can be provided over encapsulant 1352 and modules 102, 112. Carrier 1402 can comprise structures and manufacturing techniques similar to those of other carriers described herein. In some examples, carrier 1402 comprises a temporary bond layer.

Removal of carrier 1301 exposes encapsulant 1352, vertical interconnects 608, and bridge interconnects 622b. Redistribution structure 1360, as previously described, can be provided over the exposed sides of encapsulant 1352, vertical interconnects 608, and bridge interconnects 622b. Redistribution structure 1360 includes dielectric structure 1364 and conductive structure 1366, as previously described. Inner terminals 1366a of conductive structure 1366 can be coupled to vertical interconnects 608 and bridge interconnects 622b. Outer terminals 1366b of conductive structure 1366 can be exposed at the outer side of redistribution structure 1360.

FIG. 15G shows electronic device 1300 at a later stage of manufacture. In the example of FIG. 15G, external interconnects 1324 can be coupled to the outer side of redistribution structure 1360. External interconnects 1324 can be provided on outer terminals 1366b of conductive structure 1366. In some examples, electronic components 1326 can be coupled to outer terminals 1366b at the outer side of redistribution structure 1360. In some examples, a singulation can be performed to separate individual electronic devices 1300 from one another. Singulation can include cutting or sawing through encapsulant 1352, redistribution structure 640, encapsulant 630, and redistribution structure 1360. In some examples, after singulation encapsulant 1352, redistribution structure 640, encapsulant 630, and redistribution structure 1360 can be substantially coplanar with one another.

Electronic device of the present disclosure can comprise multiple bridge die variously coupling electronic components with one another. The bridge die can carry electronic signals between coupled electronic modules. Bridge die (e.g., 108 in FIG. 1) coupling electronic components can be embedded in devices at a different vertical levels than the bridge die coupling electronic modules (e.g., 122 in FIG. 1). Using bridge die to couple modules and die as described herein can improve yield and reduce complexity of substrates and redistribution structures.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a substrate;
a first module coupled to the substrate, the first module comprising:
a first electronic component;
a second electronic component disposed adjacent the first electronic component; and
a first bridge die coupled to the first electronic component and the second electronic component, wherein the first electronic component and the second electronic component are in communication across the first bridge die;
a second module coupled to the substrate adjacent the first module; and
a second bridge die coupled to the substrate, the first module, and the second module, wherein the first module and the second module are in communication across the second bridge die.

2. The electronic device of claim 1, wherein the substrate defines a cavity with the second bridge die disposed in the cavity.

3. The electronic device of claim 2, further comprising a redistribution structure disposed over the substrate and covering the cavity.

4. The electronic device of claim 1, wherein the substrate comprises a redistribution structure disposed between the second bridge die and the first module, wherein the redistribution structure is disposed between the second bridge die and the second module.

5. The electronic device of claim 4, further comprising a stiffener coupled to the redistribution structure around the first module and the second module.

6. The electronic device of claim 4, further comprising a lid coupled to the redistribution structure by an adhesive.

7. The electronic device of claim 4, wherein the first module further comprises an interconnect component coupled to the first electronic component.

8. The electronic device of claim 7, wherein the first electronic component of the first module is in communication with the second module through the interconnect component and through the second bridge die.

9. The electronic device of claim 7, wherein the first bridge die and the interconnect component are embedded in an encapsulant of the first module.

10. The electronic device of claim 1, further comprising a backside metallization coupled to the second module and to the first electronic component and the second electronic component of the first module.

11. An electronic device comprising:
a module bridge;
vertical interconnects disposed around the module bridge;
an encapsulant disposed around the module bridge and the vertical interconnects;
a first redistribution structure coupled to a first side of the module bridge and the vertical interconnects;
a first module coupled to the first redistribution structure, the first module comprising:
a die bridge;
a first processor die in communication with the die bridge; and
a first memory die adjacent the first processor die and in communication with the first processor die through the die bridge; and
a second module coupled to the first redistribution structure and in communication with the first module through the module bridge.

12. The electronic device of claim 11, further comprising a second redistribution structure coupled to the vertical interconnects and to a second side of the module bridge opposite the first side.

13. The electronic device of claim 11, wherein the module bridge comprises a long bridge coupling the first processor die of the first module to a second processor die of the second module.

14. The electronic device of claim 11, wherein the module bridge comprises a short bridge coupling the first processor die of the first module to a second processor die of the second module.

15. The electronic device of claim 14, wherein a footprint of the short bridge is outside of a first footprint of the first processor die and a second footprint of the second processor die.

16. The electronic device of claim 11, wherein the first processor die is in communication with the first memory die through the die bridge, wherein the first processor die is in communication with a second processor die of the second module through the die bridge.

17. A method of manufacturing an electronic device, comprising:
providing a module bridge die;
providing vertical interconnects around the module bridge die;
providing a first redistribution structure over the module bridge die and the vertical interconnects;
providing a first module coupled to the first redistribution structure, the first module comprising a first electronic component, a component bridge die coupled to the first electronic component, and a second electronic component coupled to the component bridge die, wherein the first electronic component and second electronic component are in communication across the component bridge die; and
providing a second module coupled to the first redistribution structure, wherein the first module and the second module are in communication across the module bridge die.

18. The method of claim 17, further comprising providing a second redistribution structure over an exposed side of the module bridge die opposite the first redistribution structure.

19. The method of claim 17, further comprising providing a base substrate comprising interior sidewalls defining a cavity, wherein the module bridge die is provided in the cavity.

20. The method of claim 17, providing a backside metallization over the first module and the second module.
